(19) United States
(12) Patent Application Publication
(10) Pub. No.: US 2026/0191013 A1
(43) Pub. Date: Jul. 2, 2026

(54) ELECTRONIC DEVICE

(71) Applicant: DENSO CORPORATION, Kariya-city (JP)

(72) Inventors: Noboru NAGASE, Kariya-city (JP); Shunji KUNII, Kariya-city (JP); Atsushi SAITO, Kariya-city (JP); Takahiro NAKANO, Kariya-city (JP); Yoshifumi OHSHIMA, Kariya-city (JP); Toshihiro FUJITA, Kariya-city (JP); Ippei KAWAMOTO, Kariya-city (JP)

(21) Appl. No.: 19/547,131

(22) Filed: Feb. 23, 2026

Related U.S. Application Data
(63) Continuation of application No. PCT/JP2024/027562, filed on Aug. 1, 2024.

(30) Foreign Application Priority Data
Aug. 25, 2023 (JP) 2023-137530

(51) Int. Cl. H10W 42/80; H10W 70/40; H10W 90/00; H10W 90/10

(52) U.S. Cl. CPC H10W 42/80; H10W 70/479; H10W 90/10; H10W 90/764

(57) ABSTRACT

An electronic device includes a wiring member and an encapsulating body that encapsulates the wiring member. The wiring member includes a fuse portion extending in a predetermined direction and an extension portion continuous and integral with the fuse portion. The extension portion extends in a direction different from the predetermined direction at least in a portion, and is melted by heat generated from the fuse portion due to energization. The encapsulating body includes an outflow passage that has a portion covering an outer peripheral surface of the extension portion. The outflow passage extends along the extension portion and defines an opening on an outer surface of the encapsulating body for releasing the fuse portion and the extension portion, which are melted due to the energization, to the outside of the encapsulating body.

### CROSS REFERENCE TO RELATED APPLICATIONS

The present application is a continuation application of International Patent Application No. PCT/JP2024/027562 filed on Aug. 1, 2024, which designated the U.S. and claims the benefit of priority from Japanese Patent Application No. 2023-137530 filed on Aug. 25, 2023. The entire disclosures of all of the above applications are incorporated herein by reference.

### TECHNICAL FIELD

The present disclosure relates to an electronic device.

### BACKGROUND

JP 2011-146539 A discloses an electronic device including a wiring member having a fuse portion and an encapsulating body encapsulating the wiring member. The contents described in JP 2011-146539 A are incorporated herein by reference as explanations of technical elements in the present disclosure.

### SUMMARY

According to an aspect of the present disclosure, an electronic device includes a wiring member and an encapsulating body that encapsulates the wiring member. The wiring member may include a fuse portion extending in a predetermined direction and an extension portion continuous and integral with the fuse portion. The extension portion may extend in a direction different from the predetermined direction at least in a portion, and be melted by heat generated from the fuse portion due to energization. The encapsulating body may include an outflow passage that has a portion covering an outer peripheral surface of the extension portion. The outflow passage may extend along the extension portion and define an opening on an outer surface of the encapsulating body for releasing the fuse portion and the extension portion, which are melted due to the energization, to the outside of the encapsulating body.

### BRIEF DESCRIPTION OF DRAWINGS

Features and advantages of the present disclosure will become more apparent from the following detailed description made with reference to the accompanying drawings, in which:

FIG. 1 is a diagram showing an equivalent circuit of an electronic device according to a first embodiment;

FIG. 2 is a plan view of the electronic device as viewed from one side;

FIG. 3 is a plan view of the electronic device as viewed from a back side;

FIG. 4 is a side view of the electronic device as viewed along an arrow Y1 in FIG. 2;

FIG. 5 is a cross-sectional view taken along a line V-V in FIG. 2;

FIG. 6 is a cross-sectional view taken along a line VI-VI in FIG. 2;

FIG. 7 is a cross-sectional view taken along a line VII-VII in FIG. 2;

FIG. 8 is an enlarged view of a region VIII shown in FIG. 4;

FIG. 9 is a flowchart showing a manufacturing method;

FIG. 10 is a diagram showing a lead frame;

FIG. 11 is a side view as viewed along an arrow Y2 in FIG. 10;

FIG. 12 is a diagram showing the arrangement of semiconductor elements;

FIG. 13 is a diagram showing the arrangement of clips;

FIG. 14 is a diagram showing molding of an encapsulating body;

FIG. 15 is a side view as viewed along an arrow Y3 in FIG. 14;

FIG. 16 is a diagram showing dicing;

FIG. 17 is a diagram showing a cross-sectional shape of the lead frame;

FIG. 18 is a diagram showing current concentration;

FIG. 19 is a diagram showing a state where a molten portion flows out;

FIG. 20 is a plan view showing a state after a fuse portion has flowed out;

FIG. 21 is a cross-sectional view showing the state after the fuse portion has flowed out;

FIG. 22 is a plan view of an electronic device, as viewed from a back side, according to a second embodiment;

FIG. 23 is a cross-sectional view of the electronic device;

FIG. 24 is a diagram showing an equivalent circuit of an electronic device according to a third embodiment;

FIG. 25 is a plan view of the electronic device as viewed from one side;

FIG. 26 is a plan view of the electronic device as viewed from a back side;

FIG. 27 is a side view of the electronic device as viewed along an arrow Y4 in FIG. 25;

FIG. 28 is a cross-sectional view taken along a line XXVIII-XXVIII in FIG. 25;

FIG. 29 is a plan view of an electronic device, as viewed from one side, according to a fourth embodiment;

FIG. 30 is a side view of the electronic device as viewed along an arrow Y5 in FIG. 29;

FIG. 31 is a cross-sectional view taken along a line XXXI-XXXI in FIG. 29;

FIG. 32 is a plan view of an electronic device, as viewed from one side, according to a fifth embodiment;

FIG. 33 is a side view of the electronic device as viewed along an arrow X1 in FIG. 32;

FIG. 34 is a cross-sectional view taken along a line XXXIV-XXXIV in FIG. 32;

FIG. 35 is a plan view of an electronic device, as viewed from one side, according to a sixth embodiment;

FIG. 36 is a plan view of the electronic device as viewed from a back side;

FIG. 37 is a cross-sectional view taken along a line XXXVII-XXXVII in FIG. 35;

FIG. 38 is a plan view of an electronic device, as viewed from one side, according to a seventh embodiment;

FIG. 39 is a cross-sectional view taken along a line XXXIX-XXXIX in FIG. 38;

FIG. 40 is a plan view of an electronic device, as viewed from one side, according to an eighth embodiment;

FIG. 41 is a plan view of the electronic device as viewed from a back side;

FIG. 42 is a plan view of an electronic device, as viewed from one side, according to a ninth embodiment;

FIG. 43 is a side view of the electronic device as viewed along an arrow Y6 in FIG. 42;

FIG. 44 is a cross-sectional view taken along a line XLIV-XLIV in FIG. 42;

FIG. 45 is a plan view of an electronic device, as viewed from one side, according to a tenth embodiment;

FIG. 46 is a plan view of the electronic device as viewed from a back side;

FIG. 47 is a plan view of an electronic device, as viewed from one side according to an eleventh embodiment;

FIG. 48 is a cross-sectional view taken along a line XLVIII-XLVIII in FIG. 47;

FIG. 49 is a plan view of an electronic device, as viewed from one side, according to a twelfth embodiment;

FIG. 50 is a plan view of the electronic device as viewed from a back side;

FIG. 51 is a side view of the electronic device as viewed along an arrow Y7 in FIG. 49;

FIG. 52 is a cross-sectional view taken along a line LII-LII in FIG. 49;

FIG. 53 is a cross-sectional view of an extension part of an electronic device according to a thirteenth embodiment;

FIG. 54 is a diagram showing cross-sectional views of other examples; and

FIG. 55 is a diagram showing cross-sectional views of other examples.

### DETAILED DESCRIPTION

In an electronic device described in JP 2011-146539 A, an encapsulating body (molded member) is molded in a state where a mold for molding the encapsulating body is in contact with a surface of a fuse portion (connection portion), so that at least a part of the fuse portion is exposed from the encapsulating body. In this case, there is a possibility that the fuse portion may not exhibit the desired interrupting characteristic due to variations in the dimensions of the fuse portion or the mold, or due to variations in the relative position between the fuse portion and the mold.

In addition, electronic devices having a structure in which a fuse portion is encapsulated are also known. In such a structure, when a fuse portion melts, the resulting increase in pressure causes the molten fuse portion to break through the encapsulating body and to be released outside the encapsulating body, resulting in disconnection. In this case, there is a possibility that the fuse portion may not exhibit the desired interrupting characteristic due to variations in the thickness of the encapsulating body covering the fuse portion or the like. From the above viewpoints, or from other viewpoints not mentioned, further improvements are required for electronic devices.

The present disclosure provides an electronic device capable of exhibiting a desired interrupting characteristic.

According to an aspect of the present disclosure, an electronic device includes a wiring member and an encapsulating body that encapsulates the wiring member. The wiring member includes a fuse portion extending in a predetermined direction and an extension portion continuous and integral with the fuse portion. The extension portion extends in a direction different from the predetermined direction at least in a portion, and is melted by heat that is generated from the fuse portion due to energization. The encapsulating body includes an outflow passage that has a portion covering an outer peripheral surface of the extension portion. The outflow passage extends along the extension portion and defines an opening on an outer surface of the encapsulating body for releasing the fuse portion and the extension portion, which are melted due to the energization, to the outside of the encapsulating body.

According to the electronic device described above, the wiring member has the extension portion. The extension portion is configured to be melted by the heat generated from the fuse portion due to energization. The encapsulating body has the outflow passage, which is formed by covering the extension portion and is thus derived from the extension portion. Before the extension portion melts, the outflow passage is blocked by the extension portion. When the extension portion melts, the outflow passage serves as a passage for releasing the molten fuse portion and extension portion outside the encapsulating body. Accordingly, it is possible to release the fuse portion, which melts due to energization, to the outside of the encapsulating body through the outflow passage, without bringing the mold into contact with the fuse portion when molding the encapsulating body. Therefore, it is possible to exhibit the desired interrupting characteristic.

Hereinafter, multiple embodiments will be described with reference to the drawings. Note that the same reference numerals are used for corresponding components throughout the embodiments, and redundant explanations may be omitted. In cases where only a portion of the configuration is described in an embodiment, the remaining portions of the configuration may be implemented by applying the structure described in another preceding embodiment. Furthermore, not only the explicitly described combinations of components in each embodiment, but also, unless there is a particular hindrance to combination, components from multiple embodiments may be partially combined even if such combinations are not expressly indicated. Additionally, the phrase “A and/or B” refers to at least one of A or B; that is, it may encompass only A, only B, or both A and B.

### First Embodiment

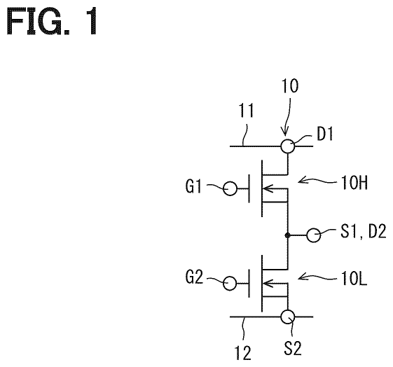

First, with reference to FIG. 1, a circuit configuration of an electronic device will be explained.

### Circuit Configuration of Electronic Device

FIG. 1 shows an equivalent circuit of the electronic device. The electronic device according to the present embodiment provides an upper and lower arm circuit 10 for one phase. The upper and lower arm circuit 10 constitutes an inverter. The inverter is configured to include the upper and lower arm circuits 10 for three phases, i.e., to include three electronic devices. The inverter is a DC-AC conversion circuit. The inverter converts a direct current (DC) voltage into a three-phase alternating current (AC) voltage in accordance with a switching control by a control circuit (not shown), and outputs it to a rotary electric machine.

The upper and lower arm circuit 10 includes an upper arm 10H and a lower arm 10L. The upper and lower arm circuit 10 is a series circuit of the upper arm 10H and the lower arm 10L. In the series circuit, the upper arm 10H is a high-side arm, and the lower arm 10L is a low-side arm. Hereinafter, the upper arm 10H and the lower arm 10L may be simply referred to as the arm 10H and the arm 10L, respectively.

In an example shown in FIG. 1, a switching element constituting each of the arms 10H and 10L is an n-channel type MOSFET. MOSFET is an abbreviation for a metal oxide semiconductor field effect transistor. The number of switching elements constituting each of the arms 10H and 10L is not particularly limited. Each of the arms 10H and 10L may include one or more switching elements. In the example shown in FIG. 1, each of the arms 10H and 10L includes one MOSFET.

The upper and lower arm circuit 10 has gate terminals G1 and G2 as external connection terminals. The gate terminal G1 is electrically connected to a gate electrode of the MOSFET on the upper arm 10H side. The gate terminal G2 is electrically connected to a gate electrode of the MOSFET on the lower arm 10L side. The gate terminals G1 and G2 are terminals for inputting gate drive signals to the corresponding gate electrodes. The upper and lower arm circuit 10 has drain terminals D1 and D2 and source terminals S1 and S2. The drain terminal D1 is electrically connected to a drain electrode of the MOSFET on the upper arm 10H side. The source terminal S1 is electrically connected to a source electrode of the MOSFET on the upper arm 10H side. The drain terminal D2 is electrically connected to a drain electrode of the MOSFET on the lower arm 10L side. The source terminal S2 is electrically connected to a source electrode of the MOSFET on the lower arm 10L side.

The source electrode of the MOSFET on the upper arm 10H side and the drain electrode of the MOSFET on the lower arm 10L side are electrically connected to each other. The source terminal S1 and/or the drain terminal D2 are electrically connected to a winding of a corresponding phase of the rotary electric machine via an output line. The drain terminal D1 is electrically connected to a P-line 11, which is a power supply line on a high potential side. The source terminal S2 on the lower arm 10L side is electrically connected to an N-line 12, which is a power supply line on a low potential side.

Note that the switching element is not limited to the MOSFET. For example, the switching element may be an IGBT. IGBT is an abbreviation for an insulated gate bipolar transistor. Each switching element may have a freewheeling diode connected in anti-parallel. Although an example in which the electronic device is applied to an inverter is illustrated, application of the electronic device is not limited to this example. For example, the electronic device may be applied to an H-bridge circuit or to a converter, which is a DC-DC conversion circuit. In place of the source terminal S1 and the drain terminal D2, output terminals may be included as external connection terminals. The output terminals are electrically connected to the source electrode of the MOSFET on the upper arm 10H side and the drain electrode of the MOSFET on the lower arm 10L side.

### Schematic Configuration of Electronic Device

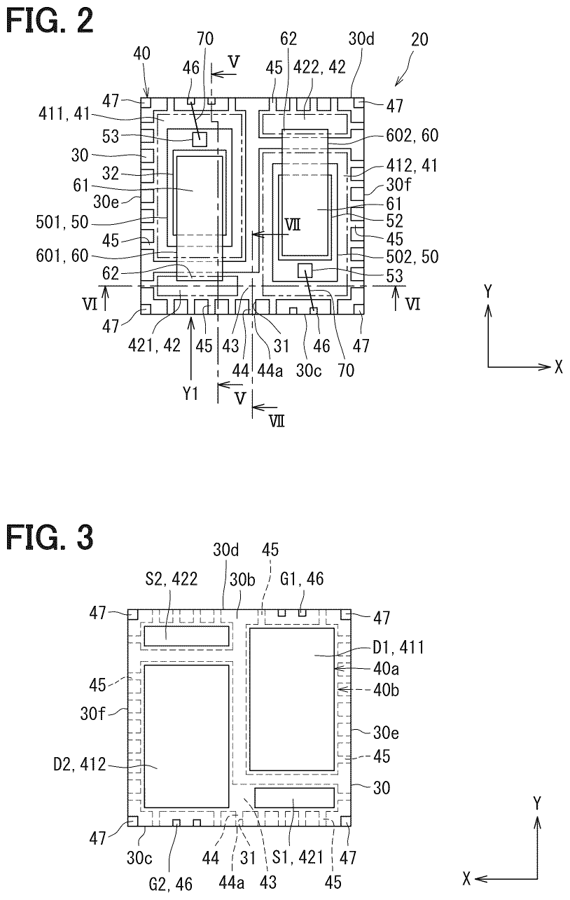

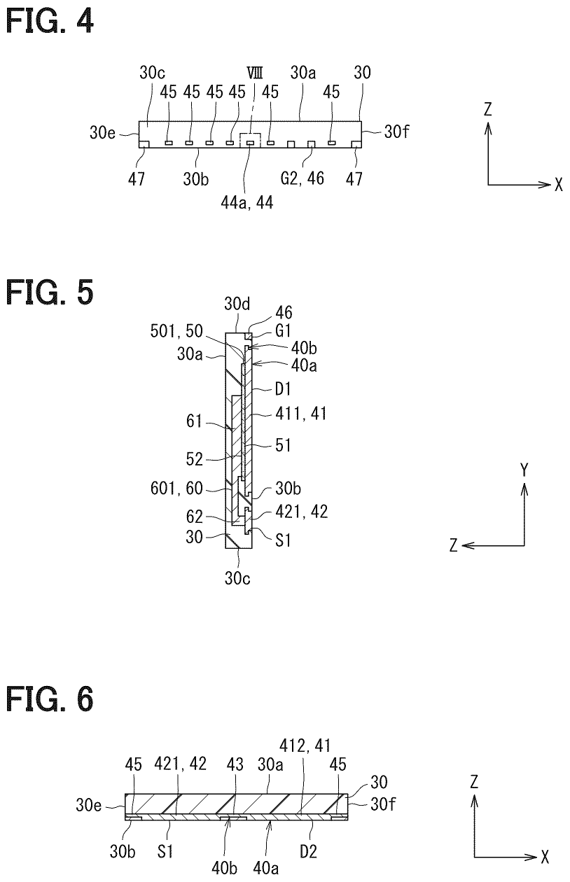

Next, with reference to FIGS. 2 to 6, a schematic configuration of the electronic device will be described. FIG. 2 is a plan view of the electronic device when viewed from one surface side of an encapsulating body. In FIG. 2, the encapsulating body is shown as transparent to indicate portions covered by the encapsulating body. FIG. 3 is a plan view of the electronic device when viewed from a back surface side of the encapsulating body. FIG. 4 is a side view when viewed along an arrow Y1 in FIG. 2. FIG. 5 is a cross-sectional view taken along a line V-V in FIG. 2. FIG. 6 is a cross-sectional view taken along a line VI-VI in FIG. 2.

In the following, a thickness direction of a lead frame is referred to as a Z direction. A direction orthogonal to the Z direction is referred to as an X direction. A direction orthogonal to both the Z and X directions is referred to as a Y direction. Unless otherwise specified, the shape as viewed in the plane from the Z direction, that is, the shape defined along an XY plane including the X and Y directions, is referred to as a planar shape. A plan view as viewed along the Z direction may be simply referred to as the plan view.

An electronic device 20 shown in FIG. 2 and other figures provides the upper and lower arm circuit 10 for one phase, as shown in FIG. 1, i.e., provides the inverter. The electronic device 20 has a 2-in-1 package structure. The electronic device 20 includes an encapsulating body 30, a lead frame 40, a semiconductor element 50, and a clip 60. The electronic device 20 including the semiconductor element 50 may be referred to as a semiconductor package or a semiconductor device.

The encapsulating body 30 encapsulates a part of the other elements constituting the electronic device 20. A remaining part of the other elements is exposed outside of the encapsulating body 30. The encapsulating body 30 is, for example, a molded body made of a resin. An example of the resin is an epoxy-based resin. The encapsulating body 30 is formed, for example, by a transfer molding method. The encapsulating body 30 may also be referred to as a molded resin or a resin molded body.

The encapsulating body 30 has, as its surfaces (outer surfaces), one surface 30a and a back surface 30b, which is opposite to the one surface 30a in the Z direction. The one surface 30a and the back surface 30b may also be referred to as a first surface and a second surface. The one surface 30a and the back surface 30b may be substantially flat. The encapsulating body 30 has side surfaces continuous with the one surface 30a and the back surface 30b. In the plan view when viewed along the Z direction, the encapsulating body 30 is substantially rectangular. The encapsulating body 30 has side surfaces 30c, 30d, 30e, and 30f. The side surface 30c is opposite to the side surface 30d in the Y direction. The side surface 30e is opposite to the side surface 30f in the X direction. The encapsulating body 30 has an outflow passage 31. Details of the outflow passage 31 will be described later.

The lead frame 40 is a plate member made of a metal having good electric conductivity, such as copper (Cu) or a Cu alloy. The lead frame 40 provides a wiring function. The lead frame 40 exemplified in the present embodiment includes a drain island 41, a source island 42, a fuse portion 43, an extension portion 44, a support lead 45, a signal terminal 46, and a reinforcement terminal 47. The lead frame 40 corresponds to a wiring member. Hereinafter, the drain island 41 and the source island 42 may be simply referred to as the islands 41 and 42.

The islands 41 and 42 are portions of the lead frame 40 on which other elements constituting the electronic device 20 are mounted. The islands 41 and 42 have the thickness direction in the Z direction. The semiconductor element 50 is connected to the drain island 41 via a bonding material such as solder (not shown). The clip 60 is connected to the source island 42 via a bonding material.

The drain island 41 includes a drain island 411 and a drain island 412. In the present embodiment, the drain island 411 constitutes the upper arm 10H, and the drain island 412 constitutes the lower arm 10L. The drain islands 411 and 412 each have a substantially rectangular shape in the plan view, and extend along the Y direction. The drain island 411 and the drain island 412 are arranged facing each other in the X direction, with a slight offset in the Y direction. The source island 42 includes a source island 421 and a source island 422. In the present embodiment, the source island 421 constitutes the upper arm 10H, and the source island 422 constitutes the lower arm 10L. The source islands 421 and 422 each have a substantially rectangular shape in the plan view, and extend along the X direction.

The source island 421 and the drain island 411 are aligned in the Y direction, with the source island 421 positioned adjacent to the side surface 30c. The source island 422 and the drain island 412 are aligned in the Y direction, with the source island 422 positioned adjacent to the side surface 30d. In this manner, the arrangement of the source island 42 relative to the drain island 41 is reversed between the upper arm 10H side and the lower arm 10L side. The islands 41 and 42 on the upper arm 10H side and the islands 41 and 42 on the lower arm 10L side are arranged in twofold symmetry.

The fuse portion 43 melts due to energization, thereby interrupting an electrical path. The fuse portion 43 generates heat and melts due to energization. When an overcurrent flows, the fuse portion 43 blows in order to protect normal circuit elements, such as the semiconductor element 50 in a normal state. The fuse portion 43 may be referred to as a fuse or cut-off section. The fuse portion 43 is provided between the source island 421 and the drain island 412. The fuse portion 43 is continuously and integrally formed with the source island 421 and the drain island 412. The fuse portion 43 is disposed at a connecting (linking) portion between the source island 421 and the drain island 412.

The fuse portion 43 extends in the X direction. One end of the fuse portion 43 is continuous with the source island 421, and the other end of the fuse portion 43 is continuous with the drain island 412. In the example shown in FIG. 2, the length of the fuse portion 43 in the Y direction, that is, the width is approximately equal to the width of the source island 421. An integral structure part including the source island 421, the fuse portion 43, and the drain island 412 has a substantially L shape in the plan view.

The extension portion 44 is continuously and integrally provided with the fuse portion 43. In the extension portion 44, at least a portion beginning from an end adjacent to the fuse portion 43 extends in a direction different from the X direction in which the fuse portion 43 extends. In the present embodiment, the extension portion 44 extends in the Y direction over its entire length. One end of the extension portion 44 is continuous with the fuse portion 43. A termination 44a, which is the other end of the extension portion 44, is substantially flush with the side surface 30c and is exposed outside of the encapsulating body 30. The termination 44a (i.e., end surface) is a cut surface.

The length of the extension portion 44 in the X direction, that is, the width in the X direction is shorter than the length (width) of the fuse portion 43 in the Y direction. A cross-sectional area of the extension portion 44 is smaller than a cross-sectional area of the fuse portion 43. The extension portion 44 melts upon receiving heat generated by the fuse portion 43 due to energization. The extension portion 44 is provided as one of the support leads 45. In the example shown in FIG. 2, one extension portion 44 is connected to the fuse portion 43.

The support leads 45 hold other elements of the lead frame 40 during the manufacturing process. The support leads 45 are cut during singulation of the electronic devices 20. The termination of the support lead 45 is also a cut surface. In the present embodiment, the support leads 45 are provided for each of the islands 41 and 42. The support leads 45 hold the islands 41 and 42. One end of each support lead 45 is continuous with a corresponding island 41 or 42, and the other end is substantially flush with the side surface of the encapsulating body 30 and exposed outside of the encapsulating body 30.

The support leads 45 extend in the X direction or Y direction. The support leads 45 extending in the X direction are exposed outside from the side surface 30c or the side surface 30d. The support leads 45 extending in the X direction are provided for each of the islands 41 and 42. The support leads 45 extending in the Y direction are exposed outside from the side surface 30e or the side surface 30f. The support leads 45 extending in the Y direction are also provided for each of the islands 41 and 42.

The signal terminal 46 is electrically connected to a pad of the semiconductor element 50. The signal terminal 46 includes at least a terminal electrically connected to a gate pad, i.e., a gate terminal. In the present embodiment, the signal terminal 46 on the upper arm 10H side is substantially flush with the side surface 30d and is exposed outside of the encapsulating body 30. The signal terminal 46 on the upper arm 10H side is disposed between the two support leads 45 in the X direction, the two support leads 45 being continuous with the drain island 411 and exposed from the side surface 30d. The signal terminal 46 on the lower arm 10L side is substantially flush with the side surface 30c and is exposed outside of the encapsulating body 30. The signal terminal 46 on the lower arm 10L side is disposed between the two support leads 45 in the X direction, the two support leads 45 being continuous with the drain island 412 and exposed from the side surface 30c.

The reinforcement terminal 47 is disposed at each of the four corners of the encapsulating body 30 in a plan view. The reinforcement terminal 47 reinforces the bonding structure in a configuration in which the electronic device 20 is soldered and bonded to a substrate (not shown). Each reinforcement terminal 47 is exposed on two adjacent side surfaces of the encapsulating body 30.

The lead frame 40 has locally varying thickness. The lead frame 40 has a thick portion 40a and a thin portion 40b, which is thinner than the thick portion 40a. An upper surface of the lead frame 40 is positioned at approximately the same height in the Z direction over the entire region. The entire upper surface is covered by the encapsulating body 30. Of the lower surface of the lead frame 40, a lower surface of the thick portion 40a is exposed from the back surface 30b of the encapsulating body 30. The lower surface of the thick portion 40a is substantially flush with the back surface 30b and exposed from the encapsulating body 30. Of the lower surface of the lead frame 40, a lower surface of the thin portion 40b is covered by the encapsulating body 30 and is not exposed from the back surface 30b. In FIG. 3, a portion of the lead frame 40 indicated by a solid line, that is, the exposed portion corresponds to the thick portion 40a, and a portion of the lead frame 40 indicated by a dashed line corresponds to the thin portion 40b.

The upper surface of the lead frame 40 is the surface adjacent to the one surface 30a of the encapsulating body 30, and the lower surface of the lead frame 40 is the surface adjacent to the back surface 30b. The lead frame 40 is formed by etching. As a result of half-etching from the lower surface of the lead frame 40, the thin portion 40b has the thickness approximately half the thickness of the thick portion 40a, and is covered by the encapsulating body 30.

Each of the islands 41 and 42 has both the thick portion 40a and the thin portion 40b. Most of the area of the islands 41 and 42 is the thick portion 40a. In the islands 41 and 42, the thin portion 40b is provided at a peripheral edge so as to surround the thick portion 40a. In FIG. 2, a two-dot chain line indicates the boundary between the thick portion 40a and the thin portion 40b in each of the islands 41 and 42. An area inside the two-dot chain line is the thick portion 40a, and an area outside the two-dot chain line is the thin portion 40b. As shown in FIG. 3, a portion of the drain island 411 exposed from the back surface 30b provides the drain terminal D1. A portion of the drain island 412 exposed from the back surface 30b provides the drain terminal D2. A portion of the source island 421 exposed from the back surface 30b provides the source terminal S1. A portion of the source island 422 exposed from the back surface 30b provides the source terminal S2.

Note that each of the islands 41 and 42 may have only the thick portion 40a. In a case where the islands 41 and 42 have the thin portion 40b in addition to the thick portion 40a, as in the present embodiment, it is possible to suppress the islands 41 and 42 from being dislodged from the encapsulating body 30 due to the anchor effect.

The fuse portion 43, the extension portion 44 and the support leads 45 are only made of the thin portion 40b. The lower surfaces of the fuse portion 43, the extension portion 44, and the support leads 45 are covered by the encapsulating body 30. The fuse portion 43, the extension portion 44, and the support leads 45 are not exposed from the back surface 30b.

The signal terminal 46 and the reinforcement terminal 47 are only made of the thick portion 40a. The signal terminal 46 and the reinforcement terminal 47 are exposed from the back surface 30b. Of the signal terminal 46, a portion of a terminal, which is electrically connected to the gate pad of the semiconductor element 50, is exposed from the back surface 30b and provides the gate terminal. Specifically, an exposed portion of the signal terminal 46 on the upper arm 10H side provides the gate terminal G1. An exposed portion of the signal terminal 46 on the lower arm 10L side provides a gate terminal G2.

The semiconductor element 50 is configured by forming a switching element on a semiconductor substrate made of a material such as silicon (Si) or a wide bandgap semiconductor having a bandgap larger than silicon. Examples of the wide bandgap semiconductor include silicon carbide (SiC), gallium nitride (GaN), gallium oxide (Ga2O3), diamond, and the like. The semiconductor element 50 may also be referred to as a semiconductor chip or power device.

In the present embodiment, as an example, a vertical element is formed in the semiconductor substrate. The vertical element is configured to allow a main current to flow in the thickness direction of the semiconductor element 50 (semiconductor substrate). The semiconductor element 50 is disposed on a corresponding drain island 41 so that the thickness direction of the semiconductor element 50 is substantially parallel to the thickness direction of the islands 41 and 42, that is, the Z direction. The semiconductor element 50 has main electrodes on both surfaces in the thickness direction. In the present embodiment, the semiconductor element 50 is made of an n-channel MOSFET formed in the semiconductor substrate as the vertical element. As shown in FIG. 2 and FIG. 5, the semiconductor element 50 has, as main electrodes, a drain electrode 51 on one surface and a source electrode 52 on a back surface, which is opposite to the one surface. The semiconductor element 50 is disposed on the thick portion 40a of the corresponding drain island 41 such that the drain electrode 51 faces the drain island 41.

When the MOSFET is turned on, the current (main current) flows between the main electrodes, that is, between the drain electrode 51 and source electrode 52. The drain electrode 51 is the main electrode on a high potential side, and the source electrode 52 is the main electrode on a low potential side. The drain electrode 51 is formed over substantially the entire area of the one surface. The source electrode 52 is formed at a portion of the back surface.

As shown in FIG. 2, the semiconductor element 50 has a pad 53, which is a signal electrode, on the back surface. The pad 53 is formed at a position different from the source electrode 52 on the back surface. The pad 53 includes at least a gate pad. In FIG. 2, for convenience, only one pad 53 is shown. The pad 53 (gate pad) is electrically connected to a corresponding signal terminal 46 via a bonding wire 70.

The semiconductor element 50 includes a semiconductor element 501 disposed on the drain island 411 and a semiconductor element 502 disposed on the drain island 412. In the present embodiment, the semiconductor element 501 constitutes the upper arm 10H, and the semiconductor element 502 constitutes the lower arm 10L. The drain electrode 51 of the semiconductor element 501 is connected to the drain island 411 via a bonding material such as solder. The drain electrode 51 of the semiconductor element 502 is connected to the drain island 412 via a bonding material.

The semiconductor elements 501 and 502, for example, have a common structure. The semiconductor elements 501 and 502 are arranged side by side in the X direction. The semiconductor elements 501 and 502 are arranged with a slight offset in the Y direction. The semiconductor element 502 is disposed rotated approximately 180 degrees about a Z axis relative to the semiconductor element 501. The semiconductor element 50 has a substantially rectangular shape as the planar shape. In each semiconductor element 50, the source electrode 52 and the pad 53 are aligned in the Y direction. In the semiconductor element 501, the source electrode 52 is disposed adjacent to the side surface 30c of the encapsulating body 30, and the pad 53 is disposed adjacent to the side surface 30d of the encapsulating body 30. In the semiconductor element 502, the source electrode 52 is disposed adjacent to the side surface 30d, and the pad 53 is disposed adjacent to the side surface 30c.

The clip 60 may be referred to as a bridging member, an interposing member, or a metal bridge. The clip 60 is a plate member made of a metal with good electrical conductivity, such as Cu or a Cu alloy. The clip 60 may be formed by punching and press-working a metal plate with a predetermined thickness. Alternatively, the clip 60 may be formed using a profile material that varies in thickness in certain portions. The clip 60 may also be manufactured by etching.

The clip 60 electrically connects the source electrode 52 of the semiconductor element 50 to the source island 42. The clip 60 includes connection portions 61 and 62. The connection portion 61 is a portion connected to the source electrode 52. The connection portion 61 is connected to the source electrode 52 via a bonding material such as solder. The connection portion 62 is a portion connected to the source island 42. The connection portion 62 is connected to the source island 422 via a bonding material.

The clip 60 includes a clip 601 that is connected to the semiconductor element 501, and a clip 602 that is connected to the semiconductor element 502. In the present embodiment, the clip 601 constitutes the upper arm 10H and the clip 602 constitutes the lower arm 10L. The clip 601 extends in the Y direction in the plan view. The clip 601 electrically connects the source electrode 52 of the semiconductor element 501 to the source island 421. The clip 602 extends in the Y direction in the plan view and electrically connects the source electrode 52 of the semiconductor element 502 to the source island 422.

As described above, the encapsulating body 30 encapsulates the other elements constituting the electronic device 20, namely, the lead frame 40, the semiconductor element 50, and the clip 60, with the exception of the encapsulating body 30 itself. The other elements are not exposed from the one surface 30a of the encapsulating body 30. The other elements are exposed from the back surface 30b and the side surfaces 30c, 30d, 30e, and 30f. Of the lead frame 40, the islands 41 and 42 soldered and joined to the substrate, the signal terminals 46, and the reinforcement terminals 47 are exposed from the back surface 30b and are substantially flush with the back surface 30b. The support leads 45 and the reinforcement terminals 47 are exposed from the corresponding side surfaces 30c, 30d, 30e, and 30f and are substantially flush with the corresponding side surfaces 30c, 30d, 30e, and 30f. The signal terminals 46 are exposed from the corresponding side surfaces 30c and 30d and are substantially flush with the corresponding side surfaces 30c and 30d. The extension portion 44 is exposed from the side surface 30c and is substantially flush with the side surface 30c. Thus, the electronic device 20 does not have terminals extending outside from the encapsulating body 30. The electronic device 20 adopts a QFN-type leadless package structure. QFN is an abbreviation for quad flat non-lead package.

### Outflow Passage

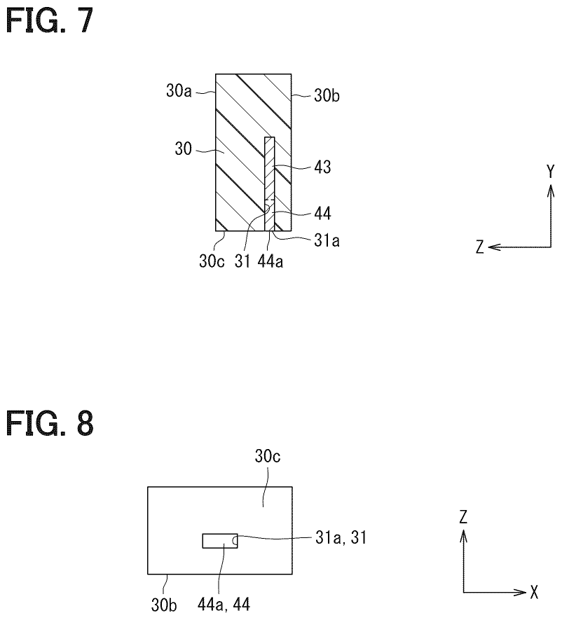

Next, with reference to FIGS. 2 to 4, 7, and 8, the outflow passage 31 will be described. FIG. 7 is a cross-sectional view taken along a line VII-VII in FIG. 2. FIG. 8 is an enlarged view of a region VIII indicated by a two-dot chain line in FIG. 4.

The outflow passage 31 serves as a passage for releasing the fuse portion 43 and the extension portion 44, which have melted due to energization, outside of the encapsulating body 30. The outflow passage 31 is configured to include at least a portion covering the outer peripheral surface of the extension portion 44. The outflow passage 31 extends along the extension portion 44 and opens on the outer surface of the encapsulating body 30. In the present embodiment, the extension portion 44 extends from the fuse portion 43 in the Y direction. The termination 44a of the extension portion 44 is substantially flush with the side surface 30c and exposed from the side surface 30c. The outflow passage 31 covers the outer peripheral surface of the extension portion 44, which extends in the Y direction, over the entire length of the extension portion 44. The outflow passage 31 opens on the side surface 30c. The encapsulating body 30 has an opening 31a of the outflow passage 31 on the side surface 30c.

The outflow passage 31 forms a cavity that has a cross-sectional area approximately equal to the cross-sectional area of the extension portion 44, extends in the Y direction from the fuse portion 43 and opens on the side surface 30c. The cavity is a hole formed in the encapsulating body 30 and extending in the Y direction from the side surface 30c. Before the extension portion 44 melts, at least a portion of the outflow passage 31 is blocked by the extension portion 44. In the present embodiment, the extension portion 44 extends from the fuse portion 43 to the side surface 30c, and the outflow passage 31 is substantially entirely blocked by the extension portion 44. The encapsulating body 30 has the outflow passage 31 that is formed by covering the extension portion 44, and is thus derived from the extension portion 44. The outflow passage 31 is disposed substantially parallel to the lower surfaces (exposed surfaces) of the islands 41 and 42 exposed from the encapsulating body 30. The outflow passage 31 is disposed substantially parallel to the back surface 30b.

### Manufacturing Method

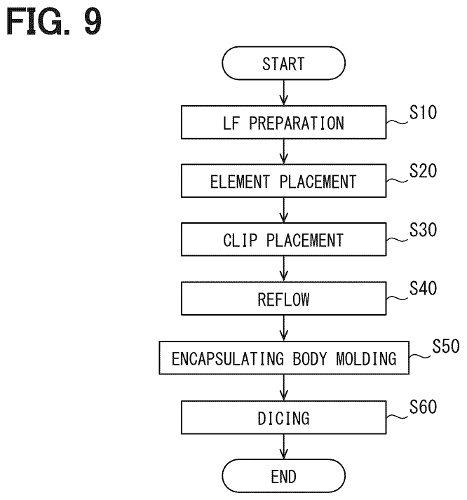

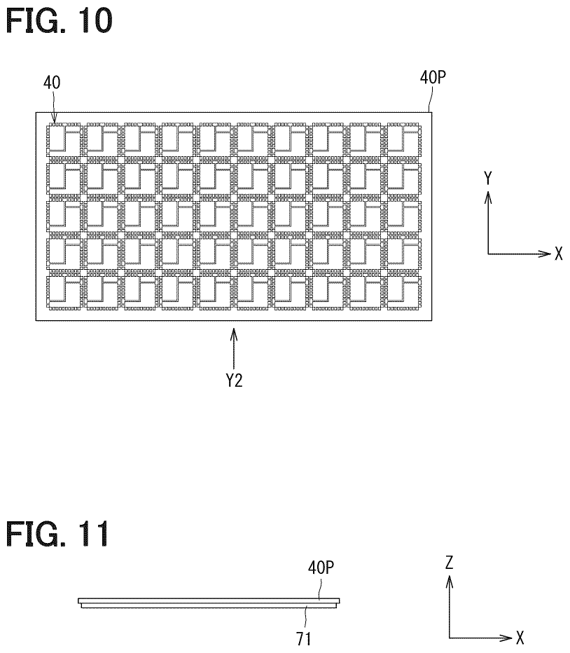

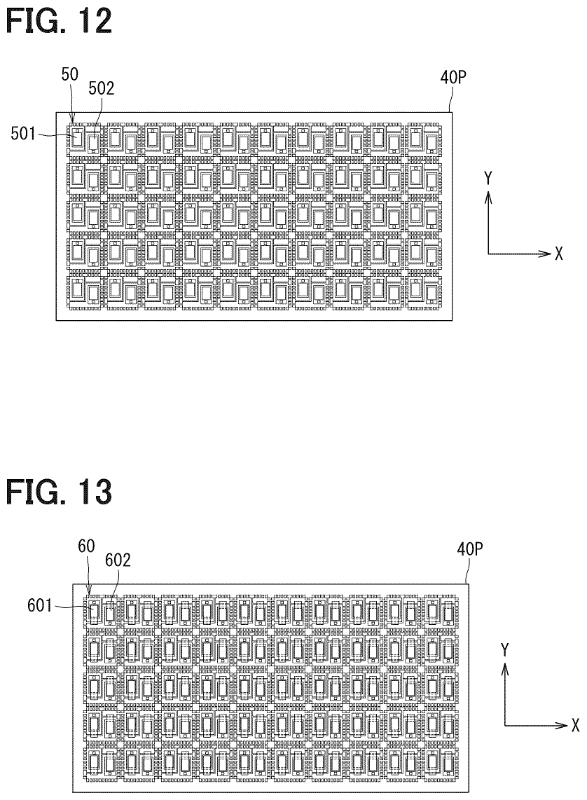

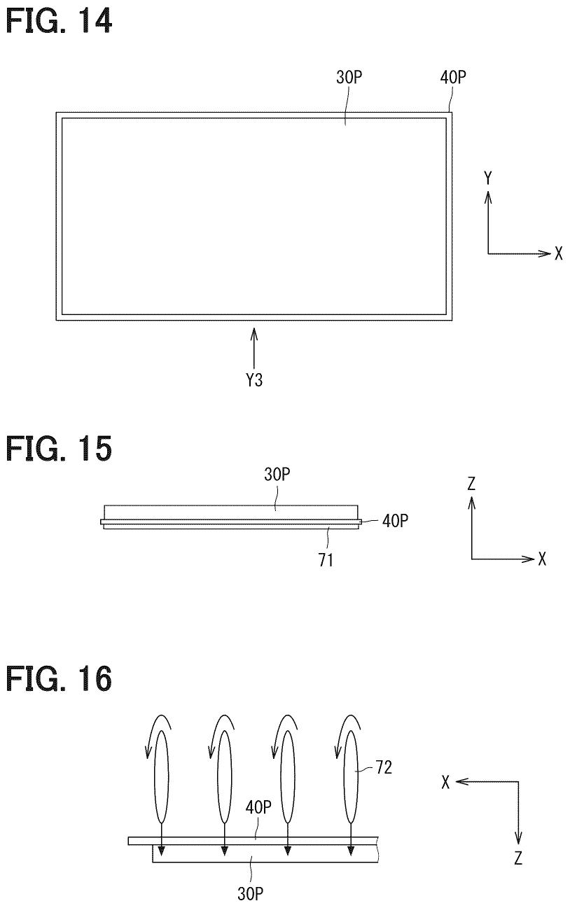

Next, with reference to FIGS. 9 to 16, an example of the manufacturing method for an electronic device 20 will be described. FIG. 9 is a flowchart showing the manufacturing method. FIG. 10 is a plan view showing a lead frame before cutting. FIG. 11 is a side view as viewed in a direction along an arrow Y2 in FIG. 10. FIG. 12 is a plan view in a state where semiconductor elements are arranged. FIG. 13 is a plan view in a state where clips are arranged. FIG. 14 is a plan view in a state where an encapsulating body is molded. FIG. 15 is a side view as viewed in a direction along an arrow Y3 in FIG. 14. FIG. 16 is a view showing dicing. In the following, an example is shown in which a solder is used as a bonding material.

As shown in FIG. 9, first, a lead frame before singulation is prepared (S10). As shown in FIG. 10, a lead frame 40P before the singulation includes elements for multiple products, that is, includes multiple lead frames 40. The multiple lead frames 40 are arranged in a matrix. The lead frame 40P includes, for example, fifty lead frames 40 in a matrix of five rows and ten columns. Each lead frame 40 is continuous with a peripheral frame or a lattice frame. The peripheral frame is provided at the outer peripheral edge of the lead frame 40P in the plan view so as to surround the multiple lead frames 40. The lattice frame is provided so as to partition the multiple lead frames 40. The lattice frame is provided between adjacent lead frames 40.

As shown in FIG. 11, a back tape 71 is affixed to substantially the entire lower surface of the prepared lead frame 40P. The back tape 71 supports each element of the lead frame 40. The back tape 71 suppresses deformation and positional displacement of each element. For example, it is possible to suppress an occurrence of resin burr during molding.

Further, a solder (not shown) is applied to a mounting section of each of the lead frames 40. For example, the solder may be applied by printing. In the case of printing, it is preferable that the front surface of the lead frame 40P is flat. Therefore, in the present embodiment, a lead frame 40P that is formed by etching a flat metal plate is used. By the etching, it is easy to form the lead frame 40 having both the thick portion 40a and the thin portion 40b. Through the etching, unnecessary portions of the flat metal plate are melted and removed. The flat metal plate is melted from both the top side and the bottom side in the Z direction. In the lead frame 40P, a through section has a cross-sectional shape in which two, substantially spherical shapes are connected in the Z direction.

Next, the semiconductor elements 50 are placed (S20). The semiconductor elements 50 are prepared in parallel with the lead frame 40P. The semiconductor elements 50 are obtained by dicing a wafer that has undergone multiple manufacturing processes into individual chips. The prepared semiconductor elements 50 are then placed at predetermined positions on the lead frame 40, specifically on the drain islands 41 described above, as shown in FIG. 12. The semiconductor elements 501 and 502 are placed on all the lead frames 40. Furthermore, the solder is applied to the source electrodes 52 of the semiconductor elements 50 placed on the lead frames 40. For example, the solder may be applied by printing.

Next, the clips 60 are placed (S30). The clips 60 are prepared in parallel with the lead frames 40 and the semiconductor elements 50. The prepared clip 60 is placed such that one end overlaps with the solder on the semiconductor element 50, and the other end overlaps with the solder at a predetermined position on the lead frame 40, specifically, on the source island 42 described above, as shown in FIG. 13. The clips 601 and 602 are placed for all the lead frames 40.

Next, solder reflow is performed (S40). As a result, the semiconductor elements 50 and the lead frames 40 are soldered and bonded. The clips 60 and the lead frames 40 are soldered and bonded. The clips 60 and the semiconductor elements 50 are also soldered and bonded. Although not illustrated, after the reflow, the pads 53 of the semiconductor elements 50 are connected to the signal terminals 46 via the bonding wires 70 described above.

Next, molding of an encapsulating body before singulation is performed (S50). As shown in FIGS. 14 and 15, an encapsulating body 30P before the singulation integrally encapsulates the elements for the multiple products. Resin is injected into a cavity of a mold in which upper and lower molds are clamped, thereby molding the encapsulating body 30P. The upper mold is configured to integrally cover all regions except the outer periphery of the lead frame 40P. A wall surface constituting the cavity of the lower mold is substantially flat. The encapsulating body 30P is molded in a state where the back tape 71 is arranged in contact with the wall surface of the cavity of the lower mold.

After the molding, the back tape 71 is removed. As a result, the lower surfaces of the thick portions 40a of the lead frames 40 are exposed. Subsequently, a plating film is applied to the exposed portions of the lead frames 40. For example, an electroplating process may be performed to form the plating film. This enhances the connection reliability between the electronic device 20 and the substrate using the solder.

Next, dicing is performed (S60). As shown in FIG. 16, the encapsulating body 30P is placed upside down in the Z direction from the orientation in the molding, and is cut from the lower surface side of the lead frames 40 using a diamond cutter 72. The diamond cutter 72 may also be referred to as a dicing cutter or dicing saw. By the dicing, the lead frame 40P is divided into lead frames 40 for each product unit. The encapsulating body 30P is divided into encapsulating bodies 30 for each product unit. In this way, the electronic device 20 is obtained.

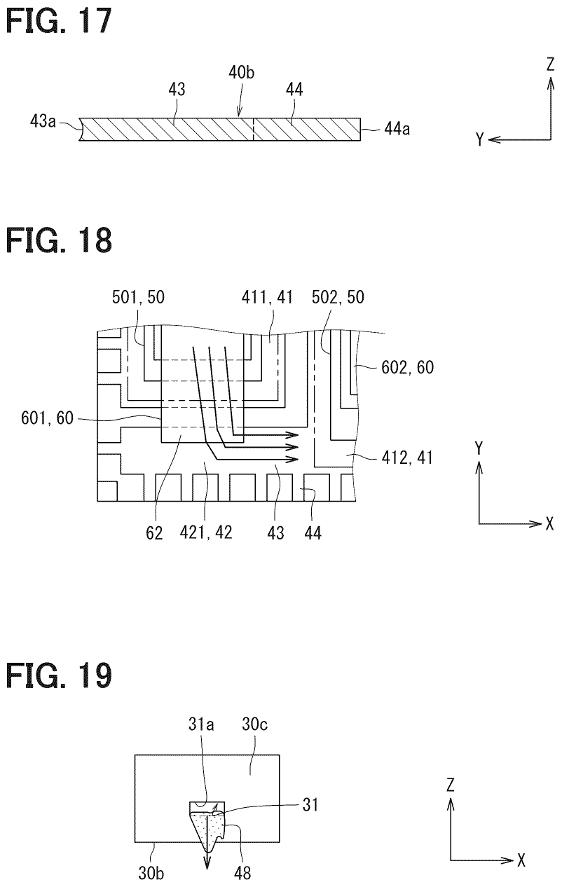

FIG. 17 shows a cross-sectional shape of the lead frame 40. FIG. 17 shows the cross-section of the thin portion 40b including the fuse portion 43 and the extension portion 44. FIG. 17 corresponds to an enlarged view of the fuse portion 43 and the extension portion 44 shown in FIG. 7. As described above, in the present embodiment, the singulation is performed by the dicing. Accordingly, the termination 44a of the extension portion 44 is the cut surface resulting from the dicing. The termination 44a is substantially flush with the side surface 30c, which is the cut surface of the encapsulating body 30 resulting from the dicing. In contrast, a side surface 43a of the fuse portion 43 is an etched surface. The etched surface has a shape resembling a portion of a sphere. Of side surfaces of the fuse portion 43, the side surface on a side to which the extension portion 44 connects also has a shape similar to the side surface 43a. The side surfaces of the extension portion 44, except for the termination 44a, also have shapes similar to the side surface 43a. Thus, the surface condition of the termination 44a of the extension portion 44 is significantly different from that of the side surfaces of the fuse portion 43. Note that, in the figures except for FIG. 17, the shape of the lead frame 40 is simplified in the illustrations.

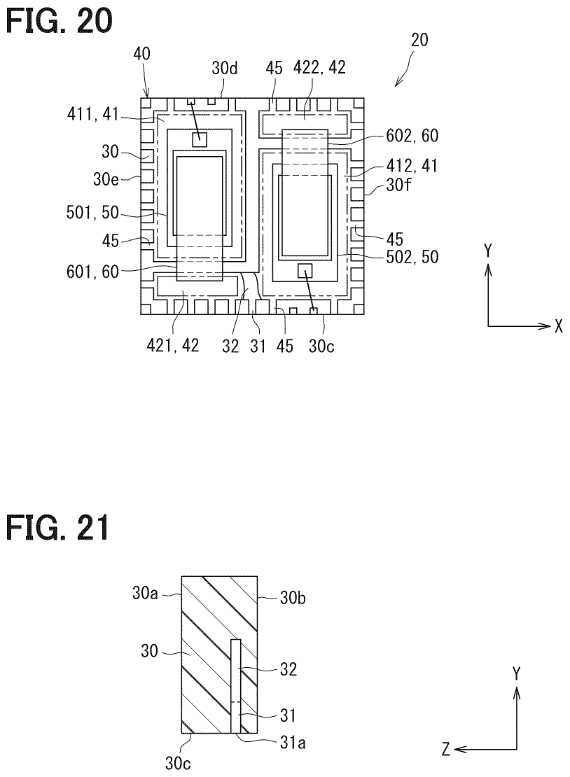

Next, with reference to FIGS. 18 to 21, a fusing operation will be described. FIG. 18 is an enlarged plan view of the vicinity of a fuse portion. FIG. 18 shows a current concentration. FIG. 19 is a plan view showing a state in which a molten portion flows out. FIG. 19 corresponds to FIG. 8. In FIG. 19, the molten portion is hatched for the sake of clarity. FIG. 20 shows a state after the molten portion has flowed out. FIG. 20 corresponds to FIG. 2. FIG. 21 is a cross-sectional view showing a state after the molten portion has flowed out. FIG. 21 corresponds to FIG. 7.

The fuse portion 43 provides the function of interrupting the electrical path as described above. The fuse portion 43 generates heat when energized. When the temperature of the fuse portion 43 exceeds the melting point of the material forming the fuse portion 43, the fuse portion 43 melts. In order to provide the interrupting function, the fuse portion 43 has at least one of a structure with high resistance and easy heat generation, a structure with low heat dissipation and high thermal retention, or a structure prone to current concentration. The fuse portion 43 in the present embodiment has all three of the structures described above.

Specifically, the thickness of the fuse portion 43 is approximately half the thickness of the thick portion 40a of the islands 41 and 42 due to the half-etching. The fuse portion 43 extends along the longitudinal direction of the source island 421 and has a narrow width. Therefore, a resistance value of the fuse portion 43 is high. The lower surface of the fuse portion 43 is covered by the encapsulating body 30, and its heat dissipation is lower than that of the islands 41, 42. As a result, the heat generated due to the energization is likely to be retained. In the plan view, the clip 601 extends in the Y direction, while the source island 421 and the fuse portion 43 extend in the X direction. When one of the semiconductor elements 501 and 502 experiences a short-circuit fault and the other is turned on, the resulting ground fault current bends at the bonded portion between the clip 601 and the source island 421, as shown by solid arrows in FIG. 18 and concentrates in the fuse portion 43.

For example, when the ground fault current is several hundred amperes, the temperature of the fuse portion 43 exceeds 1000 degrees Celsius (° C.) within several tens of milliseconds. The temperature of the fuse portion 43 exceeds the melting point of Cu, 1085° C. As a result, the fuse portion 43 melts. The extension portion 44 is continuous and integral with the fuse portion 43. Thus, the temperature of the extension portion 44 increases due to heat conduction from the fuse portion 43. The temperature of the extension portion 44 increases together with the fuse portion 43. The internal pressure increases with the increase in the temperature, and the fuse portion 43 and the extension portion 44 are forced outward through the outflow passage 31. When the temperature further increases and the fuse portion 43 and the extension portion 44 melt, a molten portion 48, as shown in FIG. 19, is extruded from the opening 31a of the outflow passage 31 to the outside of the encapsulating body 30. The molten portion 48 is a portion of the lead frame 40 that has melted due to overcurrent, and includes at least a portion of the fuse portion 43 and the extension portion 44. When the molten portion 48 flows outside the encapsulating body 30, the electric current flow is interrupted.

When the molten portion 48 flows outside the encapsulating body 30, as shown in FIGS. 20 and 21, the outflow passage 31 becomes a cavity along its entire length, with no extension portion 44 present. As the fuse portion 43 flows out, a cavity 32 originating from the fuse portion 43 is formed in the encapsulating body 30. The cavity 32 is in communication with the outflow passage 31. The cavity 32 is provided between the source island 421 and the drain island 412, and electrically isolates the source island 421 and the drain island 412 from each other. The source island 421 and the drain island 412 are thus in a disconnected state.

### Summary of First Embodiment

As exemplified in the present embodiment, when the electronic device 20 provides the upper and lower arm circuit 10 for one phase, if one of the arms 10H and 10L has a short-circuit fault and the other is turned on, an overcurrent due to ground fault will flow. Although control is performed to restrict a normal arm from failing, should a fault nevertheless occur, the semiconductor device may result in a complete power ground fault, affecting other products and adjacent circuits. The electronic device 20 of the present embodiment includes the wiring member (lead frame 40) and the encapsulating body 30 for encapsulating the wiring member. The wiring member has the fuse portion 43 extending in a predetermined direction (X direction). When an overcurrent occurs, the fuse portion 43 melts and interrupts the electrical path. Thus, it is possible to suppress a normal arm from reaching a fault condition.

The wiring member has the extension portion 44. The extension portion 44 is continuous and integral with the fuse portion 43, and at least a portion thereof extends in a direction (Y direction) different from the predetermined direction from the fuse portion 43. The extension portion 44 is configured to be melted by the heat generated from the fuse portion 43 when energized. The encapsulating body 30 is provided with the outflow passage 31 that includes at least a portion covering the outer peripheral surface of the extension portion 44 and extends along the extension portion 44.

As described above, the encapsulating body 30 has the outflow passage 31, formed by covering the extension portion 44 and thus derived from the extension portion 44. Before the extension portion 44 melts, the outflow passage 31 is blocked by the extension portion 44. When the extension portion 44 melts, the outflow passage 31 functions as a passage for releasing the melted fuse portion 43 and extension portion 44 to the outside of the encapsulating body 30. Therefore, it is not necessary to form the fuse portion to be exposed from the encapsulating body 30 by bringing the mold for molding the encapsulating body 30 with the fuse portion 43, and it is possible to release the fuse portion 43 melted due to the energization to the outside of the encapsulating body 30. The fuse portion 43 can exhibit the desired interrupting characteristic without requiring strict management of dimensional accuracy of the wiring member including the fuse portion 43 or relative positional accuracy of the wiring member including the fuse portion 43 and the mold.

As exemplified in present embodiment, the termination 44a of the extension portion 44 and the fuse portion 43 may have different surface conditions. The termination 44a may be a cut surface. The termination 44a may be substantially flush with the outer surface of the encapsulating body 30. The outflow passage 31 may be open on the side surface 30c of the encapsulating body 30. In the present embodiment, the electronic device 20 is singulated by dicing. The wiring member is formed by etching. By the dicing, the termination 44a is substantially flush with and exposed on the side surface 30c of the encapsulating body 30, and the outflow passage 31 opens on the side surface 30c. The termination 44a is the cut surface resulting from the dicing, while the fuse portion 43 has the etched surface. The extension portion 44 and the outflow passage 31 are formed through the molding process for molding the encapsulating body and the singulation process. Thus, the manufacturing process can be simplified.

As exemplified in present embodiment, the cross-sectional area of the extension portion 44 may be smaller than the cross-sectional area of the fuse portion 43. The extension portion 44 can thus be easily melted by the heat generated from the fuse portion 43 due to the energization. Therefore, when the fuse portion 43 is melted, the melted fuse portion 43 (molten portion 48) can quickly be released to the outside of the encapsulating body 30.

As exemplified in present embodiment, the wiring member may be a lead frame 40. The lead frame 40 facilitates the formation of the fuse portion 43 and the extension portion 44. For example, it is easy to locally differentiate the thickness of the lead frame 40 by etching, thereby to provide the interrupting function. For example, a portion of the support leads 45 may be used as the extension portion 44.

As exemplified in present embodiment, the electronic device 20 may include a semiconductor element 50. The lead frame 40 may have a drain island 41 (mounting portion) that is thicker than the fuse portion 43 and the extension portion 44, and to which the semiconductor element 50 is connected. The lower surface of the drain island 41 may be exposed from the encapsulating body 30, while the lower surfaces of the fuse portion 43 and the extension portion 44 may be covered by the encapsulating body 30. In present embodiment, by the half-etching, the thickness of the thin portion 40b including the fuse portion 43 and the extension portion 44 is approximately half the thickness of the thick portion 40a forming the main part of the drain island 41. Therefore, the fuse portion 43 and the extension portion 44 can be provided with desired functions, and the heat generated by the semiconductor element 50 can be effectively dissipated.

The outflow passage 31 may be disposed substantially parallel to the lower surface of the drain island 41 exposed from the encapsulating body 30. The outflow passage 31 may extend substantially parallel to the lower surface of the drain island 41. In such configurations, the outflow passage 31 can be provided substantially parallel to a substrate on which the electronic device 20 is mounted. Since the position of the outflow passage 31 is determined with reference to the substrate, a layout facilitating the discharge of the molten portion 48 can be readily ensured.

### Second Embodiment

A second embodiment is a modification based on the preceding embodiment, and the description of the preceding embodiment may be referenced. In the preceding embodiment, all the islands mainly have the thick portions. In contrast, at least a part of the source islands may have only a thin portion.

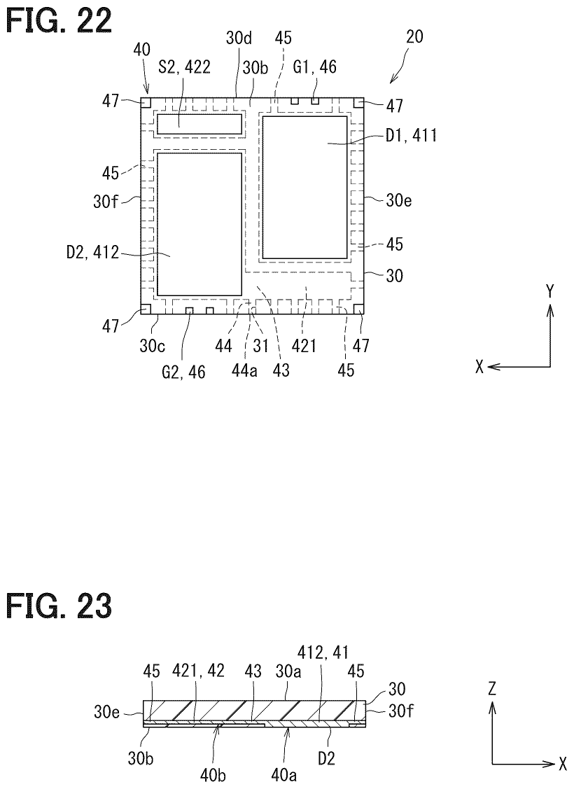

FIG. 22 is a plan view of the electronic device according to the present embodiment as viewed from the back surface side. FIG. 22 corresponds to FIG. 3. FIG. 23 is a cross-sectional view of the electronic device. FIG. 23 corresponds to FIG. 6. As shown in FIGS. 22 and 23, of the islands 41 and 42, the source island 421 has only the thin portion 40b. The drain island 41 (411, 412) and the source island 422 are mainly made of the thick portions 40a, similar to the preceding embodiment. The thickness of the source island 421 is approximately half the thickness of the thick portion 40a due to the half-etching. The lower surface of the source island 421 is covered by the encapsulating body 30. The source island 421 is not exposed from the back surface 30b. The electronic device 20 does not have the source terminal S1. The fuse portion 43 electrically connects the source island 421 and the drain island 412 in a state before the interruption. The other configurations of the present embodiment are similar to those of the electronic device 20 in the preceding embodiment.

### Summary of Second Embodiment

The electronic device 20 of the present embodiment also achieves the similar effects to those achieved in the preceding embodiment. For example, the lower surface of the drain island 41 is exposed from the encapsulating body 30, while the lower surfaces of the fuse portion 43 and the extension portion 44 are covered by the encapsulating body 30. Therefore, even when the source island 421 is made of the thin portion 40b, the electronic device 20 can exhibit the desired function of the fuse portion 43 and the extension portion 44, and can effectively dissipate the heat generated by the semiconductor element 50.

Although an example in which the source island 421 is made of the thin portion 40b is illustrated, the present disclosure is not limited to such an example. For example, the source island 422 may be made of the thin portion 40b. As another example, both the source island 421 and the source island 422 may be made of the thin portions 40b.

### Third Embodiment

A third embodiment is a modification based on the preceding embodiment(s), and the description of the preceding embodiment(s) may be referenced. In the preceding embodiment(s), the electronic device is configured to constitute the upper and lower arm circuit, that is, the inverter, for one phase. Alternatively, the electronic device may be configured to constitute a semiconductor relay.

### Circuit Configuration of Electronic Device

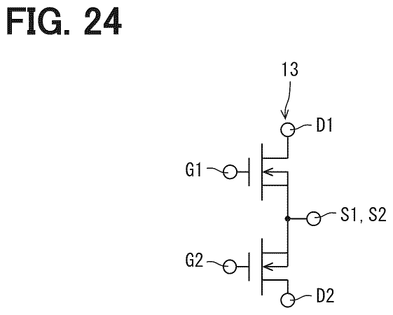

FIG. 24 shows an equivalent circuit of the electronic device according to present embodiment. As shown in FIG. 24, an electronic device 20 of present embodiment provides a source-common type semiconductor relay 13. The semiconductor relay 13 has two MOSFETs connected in series, similarly to the upper and lower arm circuit 10. The semiconductor relay 13 has, as external connection terminals, gate terminals G1 and G2, drain terminals D1 and D2, and source terminals S1 and S2. The gate terminal G1 is electrically connected to the gate electrode of one of the MOSFETs. The gate terminal G2 is electrically connected to the gate electrode of the other MOSFET. Hereinafter, the MOSFET to which the gate terminal G1 is connected is referred to as the MOSFET 1, and the MOSFET to which the gate terminal G2 is connected is referred to as the MOSFET 2.

The drain terminal D1 is electrically connected to the drain electrode of the MOSFET 1. The source terminal S1 is electrically connected to the source electrode of the MOSFET 1. The drain terminal D2 is electrically connected to the drain electrode of the MOSFET 2. The source terminal S2 is electrically connected to the source electrode of the MOSFET 2. The source electrode of the MOSFET 1 and the source electrode of the MOSFET 2 are electrically connected to each other.

### Schematic Configuration of Electronic Device

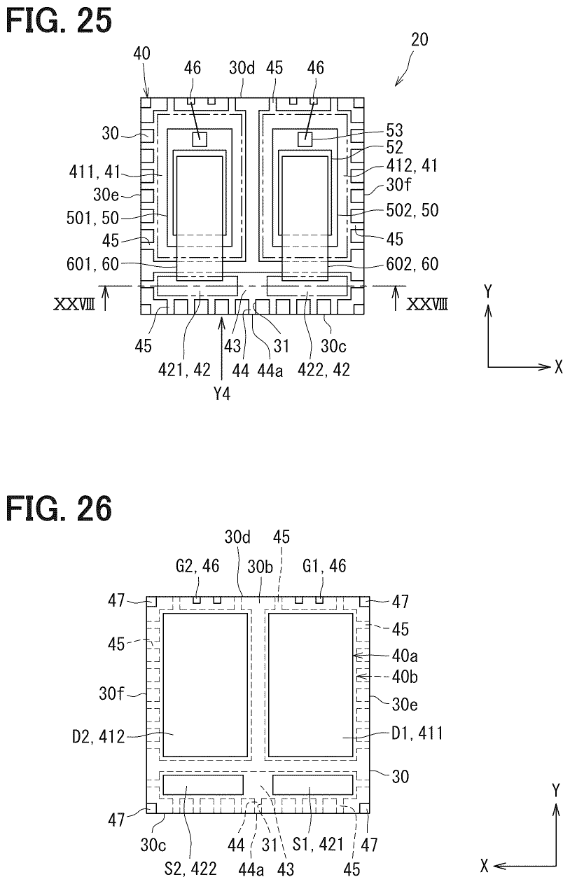

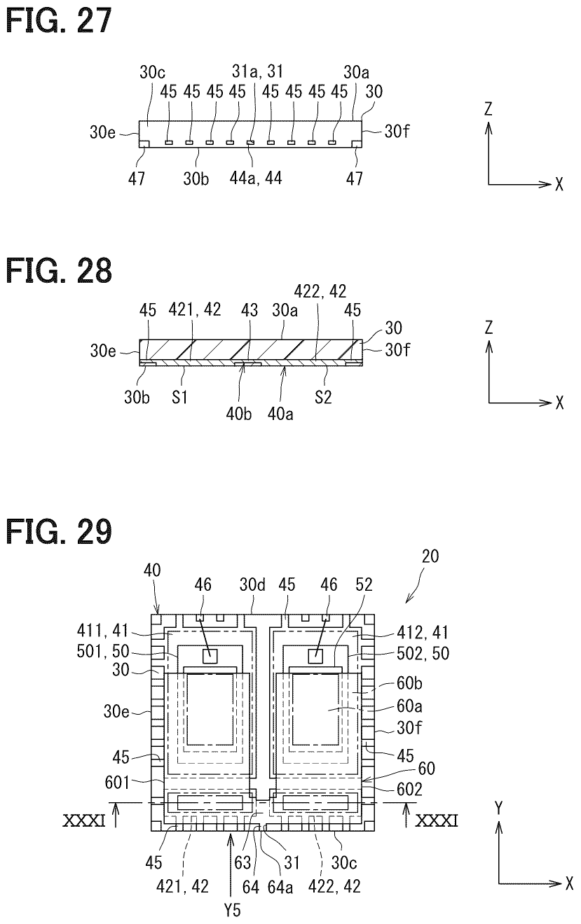

FIG. 25 is a plan view of the electronic device as viewed from a one surface side. FIG. 25 corresponds to FIG. 2. In FIG. 25, the encapsulating body is shown as transparent to indicate the portions covered by the encapsulating body, similar to FIG. 2. FIG. 26 is a plan view as viewed from a back surface side of the electronic device. FIG. 27 is a side view as viewed in a direction along an arrow Y4 in FIG. 25. FIG. 28 is a cross-sectional view taken along a line XXVIII-XXVIII in FIG. 25.

The electronic device 20 of the present embodiment also has the similar configurations to those shown in the preceding embodiment (the first embodiment). The electronic device 20 includes the encapsulating body 30, the lead frame 40, the semiconductor element 50, and the clip 60. The lead frame 40 includes the islands 41 and 42, the fuse portion 43, the extension portion 44, the support lead 45, the signal terminal 46, and the reinforcement terminal 47. The lead frame 40 has the thick portion 40a and the thin portion 40b. Most of the islands 41, 42, the signal terminal 46, and the reinforcement terminal 47 are made of the thick portion 40a. The fuse portion 43, the extension portion 44, and the support lead 45 are made of only the thin portion 40b. The upper surface of the lead frame 40 is entirely covered by the encapsulating body 30. The lower surface of the thick portion 40a is exposed from the back surface 30b, while the lower surface of the thin portion 40b is covered by the encapsulating body 30. The thick portion 40a is substantially flush with the back surface 30b and is exposed from the back surface 30b.

The drain islands 411 and 412 have a substantially rectangular shape in the plan view with the longitudinal direction along the Y direction. The drain islands 411 and 412 are arranged side by side in the X direction so as to face each other along the entire length of their longitudinal direction. The source islands 421 and 422 also have a substantially rectangular shape in the plan view with the longitudinal direction along the X direction. The source islands 421 and 422 are arranged side by side in the X direction so as to face each other along the entire length of their short-side directions.

The fuse portion 43 is provided between the source island 421 and the source island 422. The fuse portion 43 is continuous and integral with the source island 421 and the source island 422. The fuse portion 43 is disposed at a portion connecting the source island 421 and the source island 422. The length of the fuse portion 43 in the Y direction, that is, the width is approximately equal to the width of the source islands 421 and 422. The integrated structure part including the source island 421, the fuse portion 43, and the source island 422 has a substantially I-letter shape in the plan view.

The extension portion 44 is continuously and integrally formed with the fuse portion 43 and extends in the Y direction throughout its entire length. The termination 44a of the extension portion 44 is substantially flush with the side surface 30c and is exposed from the encapsulating body 30. The termination 44a is the cut surface formed by dicing. The width of the extension portion 44 is narrower than the width of the fuse portion 43. The extension portion 44 has a cross-sectional area smaller than a cross-sectional area of the fuse portion 43. The encapsulating body 30 has the outflow passage 31 that opens on the side surface 30c.

The support leads 45 are continuous with the islands 41 and 42. The terminations of the support leads 45 are substantially flush with the corresponding side surfaces 30c, 30d, 30e, and 30f of the encapsulating body 30, and are exposed from the encapsulating body 30. The signal terminal 46 corresponding to the MOSFET 1 is substantially flush with the side surface 30d and is exposed from the encapsulating body 30. The signal terminal 46 corresponding to the MOSFET 1 is disposed between two support leads 45 in the X direction, the two support leads 45 being continuous with the drain island 411 and exposed from the side surface 30d. Likewise, the signal terminal 46 corresponding to the MOSFET 2 is substantially flush with the side surface 30d and is exposed from the encapsulating body 30. The signal terminal 46 corresponding to the MOSFET 2 is disposed between the two support leads 45 in the X direction, the two support leads 45 being continuous with the drain island 412 and exposed from the side surface 30d. The reinforcement terminals 47 are provided at the four corners of the encapsulating body 30 in the plan view.

The semiconductor element 50 includes the semiconductor element 501 mounted on the drain island 411 and the semiconductor element 502 mounted on the drain island 412. The semiconductor element 501 provides the MOSFET 1, and the semiconductor element 502 provides the MOSFET 2. The semiconductor elements 501 and 502 are arranged side by side in the X direction. The semiconductor elements 501 and 502 are oriented in the same direction. The semiconductor elements 501 and 502 are disposed so that the source electrodes 52 are adjacent to the side surface 30c and the pads 53 are adjacent to the side surface 30d.

The clip 60 includes a clip 601 connected to the semiconductor element 501 and a clip 602 connected to the semiconductor element 502. The clips 601 and 602 extend in the Y direction in the plan view. The clip 601 electrically connects the source electrode 52 of the semiconductor element 501 to the source island 421. The clip 602 electrically connects the source electrode 52 of semiconductor element 502 to the source island 422. The other configurations of the present embodiment are similar to those of the preceding embodiment (the first embodiment).

### Summary of Third Embodiment

The electronic device 20 of the present embodiment also achieves the similar effects to those achieved in the preceding embodiment (the first embodiment). For example, the lead frame 40, which is the wiring member, has the fuse portion 43. When an overcurrent occurs, the fuse portion 43 melts and interrupts the electrical path. Thus, it is possible to suppress normal MOSFETs from reaching a fault condition. Further, the encapsulating body 30 has the outflow passage 31 formed by covering the extension portion 44 and derived from the extension portion 44. Before the extension portion 44 melts, the outflow passage 31 is blocked by the extension portion 44. When the extension portion 44 melts, the outflow passage 31 functions as a passage for releasing the melted fuse portion 43 and extension portion 44 to the outside of the encapsulating body 30. Even if the mold for molding the encapsulating body 30 is not brought into contact with the fuse portion 43, it is possible to release the fuse portion 43 melted due to the energization outside of the encapsulating body 30. The fuse portion 43 can exhibit the desired interrupting characteristic.

In present embodiment, the electronic device 20 is singulated by dicing, similar to the preceding embodiment. The lead frame 40 is formed by etching. The termination 44a is the cut surface resulting from the dicing, while the fuse portion 43 has the etched surface. The extension portion 44 and the outflow passage 31 are formed through the molding process for molding the encapsulating body and the singulation process. Thus, the manufacturing process can be simplified.

In present embodiment, the lower surface of the drain island 41 is exposed from the encapsulating body 30, while the lower surfaces of the fuse portion 43 and the extension portion 44 are covered by the encapsulating body 30, similar to the preceding embodiment. By the half-etching, the thickness of the thin portion 40b including the fuse portion 43 and the extension portion 44 is approximately half the thickness of the thick portion 40a forming the main part of the drain island 41. Therefore, the electronic device 20 of the present embodiment can also exhibit the desired functions of the fuse portion 43 and the extension portion 44, and can effectively dissipate the heat generated by the semiconductor element 50.

The semiconductor relay 13 is not limited to the source-common type in which the source electrodes are commonly connected. The semiconductor relay 13 may be of a drain-common type in which the drain electrodes are commonly connected. As shown in the second embodiment, at least one of the source islands 421 and 422 may be made of the thin portion 40b.

### Fourth Embodiment

A fourth embodiment is a modification based on the preceding embodiment(s), and the description of the preceding embodiment(s) may be referenced. In the preceding embodiment(s), the lead frame is used as the wiring member having the fuse portion. Alternatively, the clip may be used as the wiring member having the fuse portion.

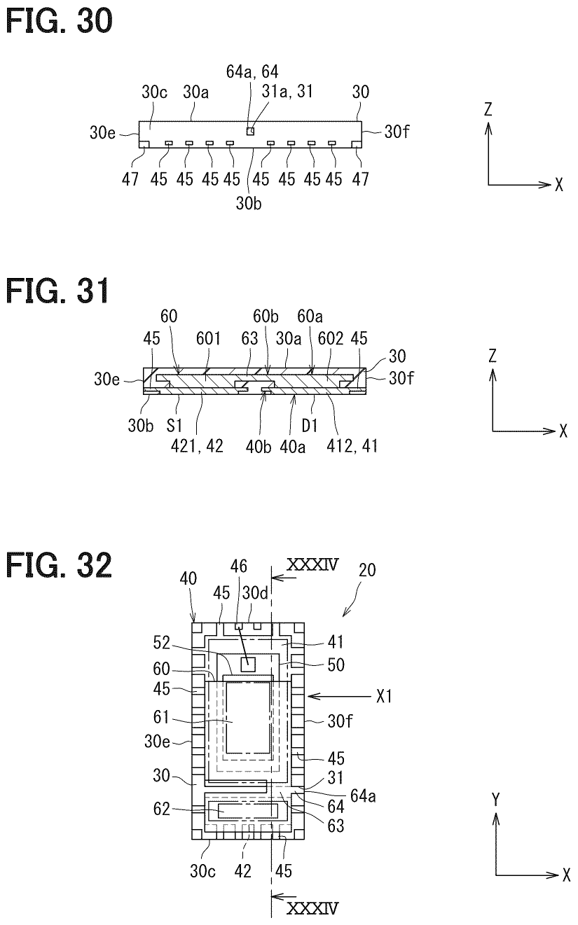

FIG. 29 is a plan view of the electronic device as viewed from the one surface side. FIG. 29 corresponds to FIG. 25. In FIG. 29, the encapsulating body is shown as transparent to indicate the portions covered by the encapsulating body. FIG. 30 is a side view as viewed in a direction along an arrow Y5 in FIG. 29. FIG. 31 is a cross-sectional view taken along a line XXXI-XXXI in FIG. 29.

The electronic device 20 of present embodiment provides the source-common type semiconductor relay 13, similar to the configuration of the preceding embodiment (the third embodiment). The difference from the third embodiment is that the clip 60 is formed with a fuse portion 63 and an extension portion 64. The lead frame 40 does not have the fuse portion 43 and the extension portion 44. The source islands 421 and 422 are arranged side by side in the X direction with a predetermined gap between them.

The fuse portion 63 is provided between the clip 601 and the clip 602. The fuse portion 63 is continuous and integral with the clip 601 and the clip 602. The fuse portion 63 is located at a portion connecting the clip 601 and the clip 602. The fuse portion 63 extends in the X direction. One end of the fuse portion 63 is continuous with the clip 601, and the other end of the fuse portion 63 is continuous with the clip 602. The length of the fuse portion 63 in the Y direction, that is, the width of the fuse portion 63 is shorter than the length (width) of the clips 601 and 602 in the X direction. The integrated structure part including the clip 601, the fuse portion 63, and the clip 602 has a substantially C-letter shape (or U-letter shape) as the planar shape. In the clip 60, the clip 601 may be referred to as a first clip portion and the clip 602 as a second clip portion.

The extension portion 64 is continuous and integral with the fuse portion 63. At least a portion of the extension portion 64 beginning from the end adjacent to the fuse portion 63 extends in a direction different from the X direction in which the fuse portion 63 extends. In the present embodiment, the extension portion 64 extends in the Y direction over its entire length. One end of the extension portion 64 is continuous with the fuse portion 63. The other end of the extension portion 64, that is, a termination 64a, is substantially flush with the side surface 30c and exposed outside of the encapsulating body 30. The termination 64a is a cut surface formed by dicing. The side surface of the fuse portion 63 is an etched surface. As shown in FIG. 30, the termination 64a is positioned above the lead frame 40, that is, farther from the back surface 30b than the lead frame 40. The fuse portion 63 and the extension portion 64 are disposed at a position farther from the substrate than the lead frame 40 in the Z direction.

The length of the extension portion 64 in the X direction, that is, the width is shorter than the length (width) of the fuse portion 63 in the Y direction. The extension portion 64 has a cross-sectional area smaller than a cross-sectional area of the fuse portion 63. The extension portion 64 melts when receiving heat generated by the fuse portion 63 when energized. In the example shown in FIG. 29, one extension portion 64 is continuous with the fuse portion 63.

The clip 60 is formed, for example, by etching. The clip 60 has locally varying thickness. The clip 60 has a thick portion 60a and a thin portion 60b, which is thinner than the thick portion 60a. The thin portion 60b has a thickness approximately half the thickness of the thick portion 60a by half-etching. In the clip 60, the portion surrounded by a one-dot chain line shown in FIG. 29 is the thick portion 60a, and the portion excluding the thick portion 60a is the thin portion 60b. The thick portion 60a is provided in the bonded portion with the source electrode 52 and the bonded portions with the source islands 421 and 422. The fuse portion 63 and the extension portion 64 are made of only the thin portion 60b.

The encapsulating body 30 has the outflow passage 31. The outflow passage 31 has at least a portion covering the outer peripheral surface of the extension portion 64. The outflow passage 31 extends along the extension portion 64 and opens on the outer surface of the encapsulating body 30. In the present embodiment, the outflow passage 31 covers the outer peripheral surface of the extension portion 64, which extends in the Y direction, over the entire length of the extension portion 64. The encapsulating body 30 has the opening 31a of the outflow passage 31 on the side surface 30c.

The outflow passage 31 is a cavity that has a cross-sectional area approximately equal to that of the extension portion 64, extends from the fuse portion 63 in the Y direction, and opens on the side surface 30c. Before the extension portion 64 melts, at least a part of the outflow passage 31 is blocked by the extension portion 64. In the present embodiment, the entire outflow passage 31 is substantially blocked by the extension portion 64. As described above, the encapsulating body 30 has the outflow passage 31 that is formed by covering the extension portion 64 and is thus derived from the extension portion 64. The outflow passage 31 is disposed substantially parallel to the lower surfaces (exposed surfaces) of the islands 41 and 42 exposed from the encapsulating body 30.

The fuse portion 63 provides the function of interrupting the electrical path. When the temperature of the fuse portion 63 exceeds the melting point of the material of the fuse portion 63, the fuse portion 63 melts. Similar to the fuse portion 43, the fuse portion 63 has at least one of a structure with high resistance and easy heat generation, a structure with low heat dissipation and high thermal retention, or a structure prone to current concentration. The fuse portion 63 in the present embodiment has all three of the structures described above.

Specifically, the thickness of the fuse portion 63 is approximately half the thickness of the bonded portion (thick portion 60a) due to the half-etching. The width of the fuse portion 63 is narrower than the width of the clips 601 and 602. Therefore, the resistance value of the fuse portion 63 is high. The lower surface of the fuse portion 63 is covered by the encapsulating body 30, so heat generated by energization is retained. In the plan view, the clip 601 extends in the Y direction, while the fuse portion 63 extends in the X direction. When one of the semiconductor elements 501 and 502 experiences a short-circuit fault and the other is turned on, the resulting overcurrent bends between the clip 601 and the fuse portion 63. As a result, the current concentrates on the fuse portion 63.

Although not illustrated, when the fuse portion 63 and the extension portion 64 melt, the molten portion is extruded from the opening 31a of the outflow passage 31 to the outside of the encapsulating body 30. The molten portion is a portion of the clip 60 that has melted due to the overcurrent and includes at least a portion of the fuse portion 63 and the extension portion 64. When the molten portion flows outside of the encapsulating body 30, the electric current flow is interrupted. After the molten portion flows outside of the encapsulating body 30, the outflow passage 31 becomes a cavity along its entire length, with no extension portion 64 present. As the fuse portion 63 flows out, a cavity derived from the fuse portion 63 is formed in the encapsulating body 30. The cavity electrically isolates the clip 601 and the clip 602. The other configurations of the present embodiment are similar to those of the preceding embodiment described above. For example, the electronic device 20 can be obtained by the manufacturing method described in the preceding embodiment (i.e., the first embodiment).

### Summary of Fourth Embodiment

The electronic device 20 of the present embodiment also achieves the similar effects to those achieved in the electronic device 20 of the preceding embodiment described above. For example, the clip 60, which is the wiring member, has the fuse portion 63. When an overcurrent flows, the fuse portion 63 melts and interrupts the electrical path. Thus, it is possible to suppress the semiconductor elements 50 in a normal state from reaching a fault condition. Further, the encapsulating body 30 has the outflow passage 31 formed by covering the extension portion 64 and originating from the extension portion 64. Before being melted, the extension portion 64 blocks the outflow passage 31. When the extension portion 64 is melted, the blocked state is released. Therefore, it is possible to release the fuse portion 63, which is melted due to the energization, to the outside of the encapsulating body 30, even without bringing the mold for molding the encapsulating body 30 into contact with the fuse portion 63. The fuse portion 63 can exhibit the desired interrupting characteristic.

In the present embodiment, the surface condition is different between the termination 64a of the extension portion 64 and the fuse portion 63. The termination 64a is the cut surface. The termination 64a is substantially flush with the outer surface of the encapsulating body 30. The outflow passage 31 opens on the outer surface of the encapsulating body 30. More specifically, the electronic device 20 is singulated by dicing. The clip 60 is formed by etching. By the dicing, the termination 64a is substantially flush with the side surface 30c and exposed from the encapsulating body 30, and the outflow passage 31 opens on the side surface 30c. The termination 64a is the cut surface resulting from the dicing, while the fuse portion 63 has the etched surface. The extension portion 64 and the outflow passage 31 are formed through the molding process for molding the encapsulating body and the singulation process. Thus, the manufacturing process can be simplified.

In the present embodiment, the clip 60 is provided with the fuse portion 63 and the extension portion 64. The fuse portion 63 and the extension portion 64 are disposed at a position higher than the lead frame 40, with reference to the lower surfaces of the islands 41 and 42 exposed from the back surface 30b of the encapsulating body 30. When the electronic device 20 is mounted on a substrate, the fuse portion 63 and the extension portion 64 are separated from a conductor pattern of the substrate. As a result, the heat dissipation of the fuse portion 63 and the extension portion 64 can be reduced. That is, the temperature of the fuse portion 63 and the extension portion 64 can be more easily increased.

It should be noted that the clip 60 may be implemented as a standalone part or as a clip frame similar to the lead frame 40. The clip frame may include clips 60 for multiple products. The clip frame may be integrally encapsulated by the encapsulating body 30P, and singulated by dicing. Although the example in which the clip 60 is formed by etching is illustrated, the clip 60 is not limited to this example. For example, the clip 60 may be formed by pressing and rolling.

In the electronic device 20 providing the upper and lower arm circuit 10, the clip 60 may be provided with the fuse portion 63 and the extension portion 64. For example, in the configuration shown in FIG. 2, the electronic device 20 may have the fuse portion 63 and the extension portion 64 in the clip 601, in place of the fuse portion 43 and the extension portion 44.

### Fifth Embodiment

A fifth embodiment is a modification based on the preceding embodiment(s), and the description of the preceding embodiment(s) may be referenced. In the preceding embodiment(s), the electronic device has the 2-in-1 package structure. In the present embodiment, alternatively, the electronic device may have a 1-in-1 package structure.

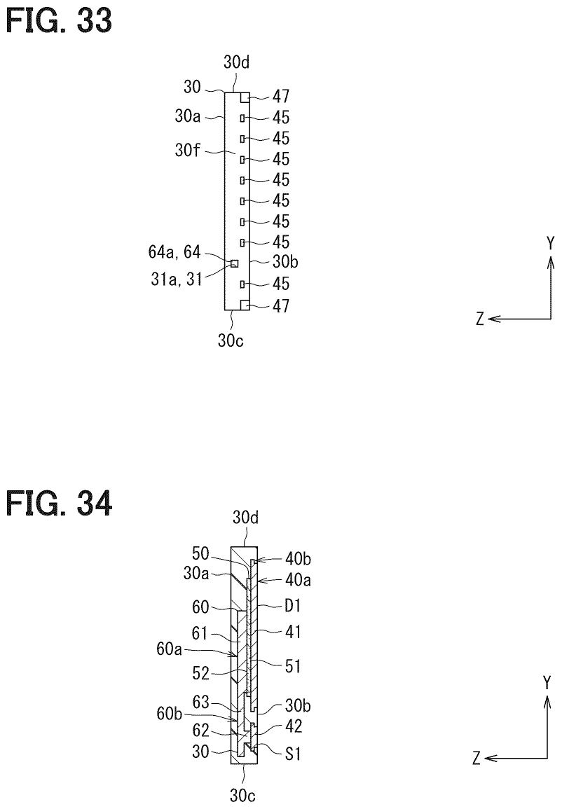

FIG. 32 is a plan view of the electronic device according to the present embodiment as viewed from the one surface side. FIG. 32 corresponds to FIG. 29. In FIG. 32, similar to FIG. 2, the encapsulating body is shown as transparent to indicate the portions covered by the encapsulating body. FIG. 33 is a side view as viewed in a direction along an arrow X1 in FIG. 32. FIG. 34 is a cross-sectional view taken along a line XXXIV-XXXIV in FIG. 32.

The electronic device 20 of the present embodiment adopts a 1-in-1 package structure. For example, the electronic device 20 may provide one arm of the upper and lower arm circuit 10 for one phase, i.e., either the upper arm 10H or the lower arm 10L. The electronic device 20 may provide one MOSFET of a series circuit in a source-common type semiconductor relay 13.

The electronic device 20 has one semiconductor element 50 and one clip 60. The lead frame 40 includes one drain island 41 and one source island 42. The drain island 41 and the source island 42 are aligned in the Y direction. The semiconductor element 50 is mounted on the drain island 41. The clip 60 extends in the Y direction in the plan view. One end of the clip 60 is connected to the source electrode 52, and the other end is connected to the source island 42.

The clip 60 includes the fuse portion 63 and the extension portion 64. The fuse portion 63 is disposed between the connection portion 61 and the connection portion 62. The fuse portion 63 is located at a portion connecting the connection portion 61 and the connection portion 62. The fuse portion 63 extends in the Y direction. The extension portion 64 extends from a side surface of the fuse portion 63 in the X direction. The termination 64a of the extension portion 64 is substantially flush with the side surface 30f and exposed outside of the encapsulating body 30. The clip 60 is formed by etching. The termination 64a is a cut surface formed by dicing, and the side surface of the fuse portion 63 is an etched surface. The outflow passage 31 covers the outer peripheral surface of the extension portion 64 extending in the X direction over the entire length of the extension portion 64. The encapsulating body 30 has an opening 31a of the outflow passage 31 on the side surface 30f. The other configurations of the present embodiment are similar to those of the preceding embodiment described above.

### Summary of Fifth Embodiment

The electronic device 20 of the present embodiment also achieves the similar effects to those achieved in the preceding embodiment described above. For example, by the dicing, the termination 64a is substantially flush with the side surface 30f of the encapsulating body 30 and exposed from the encapsulating body 30, and the outflow passage 31 opens on the side surface 30f. The termination 64a is the cut surface formed by the dicing, and the fuse portion 63 has the etched surface. The extension portion 64 and the outflow passage 31 are formed through the molding process for molding the encapsulating body and the singulation process. Thus, the manufacturing process can be simplified.

Furthermore, since the clip 60 is provided with the fuse portion 63 and extension portion 64, the heat dissipation of the fuse portion 63 and the extension portion 64 can be reduced. In other words, the temperature of the fuse portion 63 and the extension portion 64 can be more easily increased.

### Sixth Embodiment

A sixth embodiment is a modification based on the preceding embodiment(s), and the description of the preceding embodiment(s) may be referenced. In the preceding embodiment(s), the outflow passage has the opening on the side surface of the encapsulating body. Alternatively, the outflow passage may be configured to have an opening on the back surface of the encapsulating body.

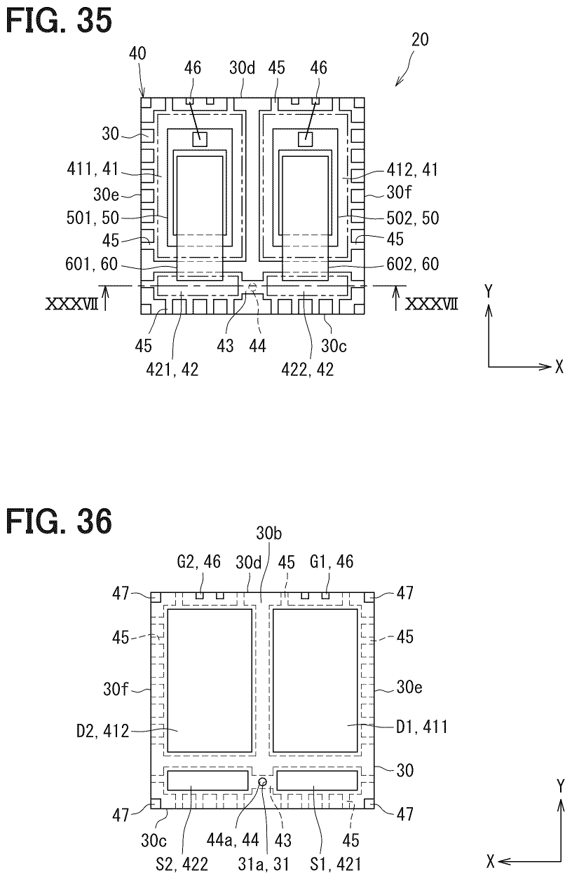

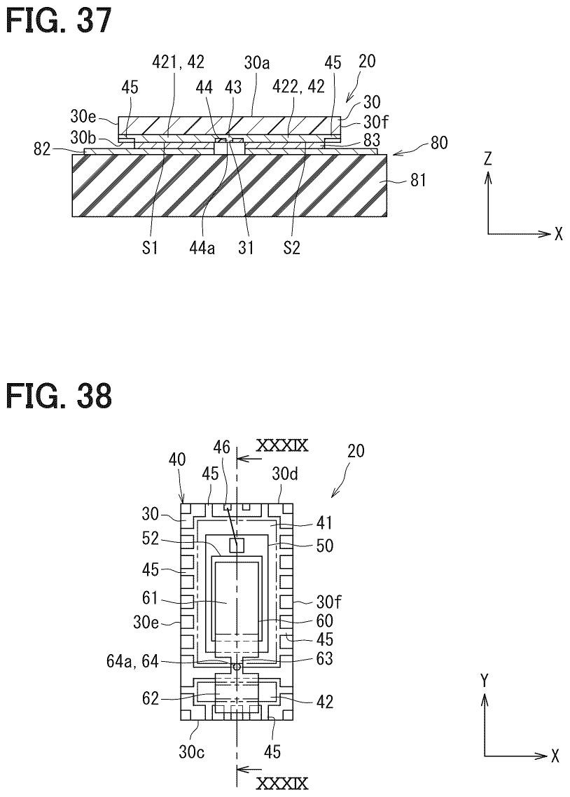

FIG. 35 is a plan view of the electronic device according to the present embodiment as viewed from the one surface side. FIG. 35 corresponds to FIG. 25. In FIG. 35, similar to FIG. 2, the encapsulating body is shown as transparent to indicate the portions covered by the encapsulating body. FIG. 36 is a plan view of the electronic device as viewed from the back surface side. FIG. 37 is a cross-sectional view taken along a line XXXVII-XXXVII in FIG. 35. FIG. 37 shows the electronic device mounted on a substrate.

The electronic device 20 of the present embodiment provides a source-common type semiconductor relay 13, similar to the electronic device 20 shown in FIG. 25. The lead frame 40 includes a fuse portion 43 and an extension portion 44. The fuse portion 43 is narrower in width than the source islands 421 and 422. The extension portion 44 extends in the Z direction from the lower surface of the fuse portion 43. The termination 44a of the extension portion 44 is substantially flush with the back surface 30b and exposed from the encapsulating body 30. The outflow passage 31 covers the outer peripheral surface of the extension portion 44 extending in the Z direction over the entire length of the extension portion 44. The outflow passage 31 opens on the back surface 30b. The encapsulating body 30 has an opening 31a of the outflow passage 31 on the back surface 30b.

As an example, the extension portion 44 has a substantially circular shape in the plan view. The planar shape of the extension portion 44 is not particularly limited. For example, the extension portion 44 may have a substantially rectangular shape in the plan view. As shown in FIG. 37, the electronic device 20 is, for example, mounted on a substrate 80. The substrate 80 is a so-called printed circuit board. The substrate 80 includes an insulating base 81 and a conductor pattern 82. The conductor pattern 82 is disposed on at least the surface of the insulating base 81 facing the electronic device 20. The conductor pattern 82 may be arranged in multiple layers in the insulating base 81. The islands 41 and 42 are connected to corresponding conductor patterns 82 via a bonding material 83 such as solder. The signal terminals 46 and the reinforcement terminals 47 are also connected to corresponding conductor patterns 82 via the bonding material 83.

When an overcurrent flows, and the fuse portion 43 and the extension portion 44 melt, the molten portion flows out from the opening 31a on the back surface 30b. Therefore, it is preferable that the electronic device 20 is connected to the substrate 80 so that the opening 31a is not blocked by the bonding material 83. With this, the molten portion can be released to the outside of the encapsulating body 30. Furthermore, it is possible to suppress the fuse portion 43 from being thermally connected to the conductor pattern 82 via the bonding material 83 and the extension portion 44. That is, it is less likely that melting of the fuse portion 43 and the extension portion 44 will be inhibited due to the heat, which is generated from the fuse portion 43, being transmitted to the conductor pattern 82.

The electronic device 20 described above can be formed by the manufacturing method illustrated in the preceding embodiment. When preparing the lead frame 40P, the lead frame 40P is etched so that a portion of the fuse portion 43 to which the extension portion 44 connects directly from below becomes the thick portion 40a. Further, the manufacturing process is proceeded up to the molding of the encapsulating body 30P in the state where the back tape 71 is attached to the back surface of the lead frame 40P. After the molding, the back tape 71 is removed. As a result, it is possible to obtain the structure in which the termination 44a is substantially flush with and exposed from the back surface 30b, and the outflow passage 31 opens on the back surface 30b. Since a plating film is applied to an exposed portion of the lead frame 40 after the back tape 71 is removed, the surface condition of the termination 44a is different from that of the surface (etched surface) of the fuse portion 43. The other configurations of the present embodiment are similar to those of the preceding embodiment described above.

### Summary of Sixth Embodiment

The electronic device 20 of the present embodiment also achieves the similar effects to those achieved in the preceding embodiment described above. For example, the encapsulating body 30 has the outflow passage 31 that is formed by covering the extension portion 44 and derived from the extension portion 44. The outflow passage 31 extends along the extension portion 44 and opens on the back surface 30b of the encapsulating body 30. Before the extension portion 44 melts, the outflow passage 31 is blocked by the extension portion 44. When the extension portion 44 melts, the outflow passage 31 functions as a passage for releasing the melted fuse portion 43 and extension portion 44 to the outside of the encapsulating body 30. Thus, even if the mold for molding the encapsulating body 30 is not brought into contact with the fuse portion 43, it is possible to release the fuse portion 43 melted due to the energization to the outside of the encapsulating body 30. The fuse portion 43 can exhibit the desired interrupting characteristic.

Although the example in which the electronic device 20 provides the semiconductor relay 13 is illustrated, the present disclosure is not limited to this example. For example, in the electronic device 20 providing the upper and lower arm circuit 10, the lead frame 40 may be provided with an extension portion 44 extending in the Z direction from the fuse portion 43 and exposed from the back surface 30b to be substantially flush with the back surface 30b.

### Seventh Embodiment

A seventh embodiment is a modification based on the preceding embodiment(s), and the description of the preceding embodiment(s) may be referenced. In the preceding embodiment(s), the outflow passage opens on the side surface or the back surface of the encapsulating body. Alternatively, the outflow passage may be configured to open on the one surface of the encapsulating body.

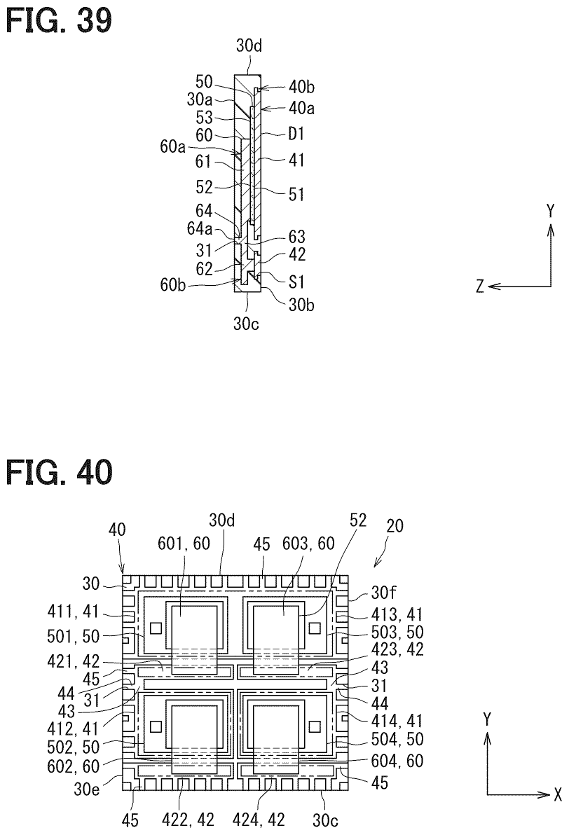

FIG. 38 is a plan view of the electronic device according to the present embodiment as viewed from the one surface side. FIG. 38 corresponds to FIG. 32. In FIG. 38, similar to FIG. 2, the encapsulating body is shown as transparent to indicate the portions covered by the encapsulating body. FIG. 39 is a cross-sectional view taken along a line XXXIX-XXXIX in FIG. 38.

The electronic device 20 of the present embodiment has a 1-in-1 package structure, similarly to the electronic device 20 shown in FIG. 32. The clip 60 includes a fuse portion 63 and an extension portion 64. The fuse portion 63 is narrower in width than the connection portions 61 and 62. The extension portion 64 extends in the Z direction from the upper surface of the fuse portion 63. The termination 64a of the extension portion 64 is substantially flush with the one surface 30a and exposed from the encapsulating body 30. The outflow passage 31 covers the outer peripheral surface of the extension portion 64 extending in the Z direction over the entire length of the extension portion 64. The encapsulating body 30 has an opening 31a of the outflow passage 31 on the one surface 30a. The other configurations of the present embodiment are similar to those of the preceding embodiment described above.

### Summary of Seventh Embodiment

The electronic device 20 of the present embodiment achieves the similar effects to those achieved in the preceding embodiment described above. For example, the encapsulating body 30 includes the outflow passage 31 formed by covering the extension portion 64 and derived from the extension portion 64. The outflow passage 31 extends along the extension portion 64 and opens on the one surface 30a of the encapsulating body 30. Before the extension portion 64 melts, the outflow passage 31 is blocked by the extension portion 64. When the extension portion 64 melts, the outflow passage 31 functions as a passage for releasing the melted fuse portion 63 and extension portion 64 to the outside of the encapsulating body 30. Thus, even if the mold for molding the encapsulating body 30 is not brought into contact with the fuse portion 63, it is possible to release the fuse portion 63, which is melted due to the energization, to the outside of the encapsulating body 30. The fuse portion 63 can exhibit the desired interrupting characteristic.

Although the example in which the electronic device 20 has the 1-in-1 package structure is illustrated, the present disclosure is not limited to this example. For example, in the 2-in-1 package structure, the clip 60 may have the extension portion 64 extending in the Z direction from the fuse portion 63 and exposed on the one surface 30a to be substantially flush with the one surface 30a.

### Eighth Embodiment

An eighth embodiment is a modification based on the preceding embodiment(s), and the description of the preceding embodiment(s) may be referenced. In the preceding embodiment(s), the electronic device is configured to provide a single system. Alternatively, the electronic device may be configured to provide multiple systems.

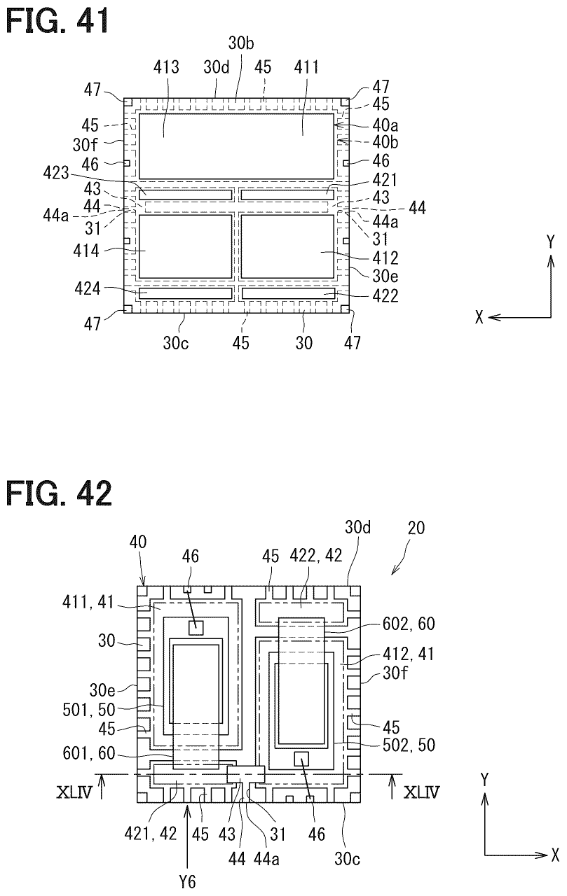

FIG. 40 is a plan view of the electronic device according to the present embodiment as viewed from the one surface side. FIG. 40 corresponds to FIG. 2. In FIG. 40, similar to FIG. 2, the encapsulating body is shown as transparent to indicate the portions covered by the encapsulating body. FIG. 41 is a plan view of the electronic device as viewed from the back surface side. FIG. 41 corresponds to FIG. 3.

The electronic device 20 of the present embodiment has a 4-in-1 package structure. The electronic device 20 provides the upper and lower arm circuits 10 for two systems. The electronic device 20 includes four semiconductor elements 50. A semiconductor element 501 constitutes the upper arm 10H of the first system, and a semiconductor element 502 constitutes the lower arm 10L of the first system. A semiconductor element 503 constitutes the upper arm 10H of the second system, and a semiconductor element 504 constitutes the lower arm 10L of the second system. The semiconductor elements 501 and 503 on the upper arm 10H side are aligned in the X direction, and the semiconductor elements 502 and 504 on the lower arm 10L side are also aligned in the X direction. The semiconductor elements 501 and 502 of the first system are aligned in the Y direction, and the semiconductor elements 503 and 504 of the second system are aligned in the Y direction.

The lead frame 40 includes the islands 41 and 42. Most of the islands 41 and 42 are made of the thick portions 40a as in the preceding embodiment. The drain island 41 includes four drain islands 411, 412, 413, and 414. The semiconductor element 501 is mounted on the drain island 411, and the semiconductor element 502 is mounted on the drain island 412. The semiconductor element 503 is mounted on the drain island 413, and the semiconductor element 504 is mounted on the drain island 414. The drain islands 411 and 413 on the upper arm 10H side are aligned in the X direction. The drain islands 411 and 413, which have a substantially equal potential, are continuous and integral. The drain islands 412 and 414 on the lower arm 10L side are aligned in the X direction.

The source island 42 includes four source islands 421, 422, 423, and 424. The islands 411, 412, 421, and 422 of the first system are aligned in the Y direction in the order of the drain island 411, the source island 421, the drain island 412, and the source island 422. The islands 413, 414, 423, and 424 of the second system are aligned in the Y direction in the order of the drain island 413, the source island 423, the drain island 414, and the source island 424.

The clip 60 includes four individual clips 601, 602, 603, and 604. Each clip 60 extends in the Y direction in the plan view. The clip 601 electrically connects the source electrode 52 of the semiconductor element 501 to the source island 421. The clip 602 electrically connects the source electrode 52 of the semiconductor element 502 to the source island 422. The clip 603 electrically connects the source electrode 52 of the semiconductor element 503 to the source island 423. The clip 604 electrically connects the source electrode 52 of the semiconductor element 504 to the source island 424.

The lead frame 40 includes a fuse portion 43 and an extension portion 44. The fuse portion 43 and the extension portion 44 are made of the thin portions 40b, as in the preceding embodiment. The fuse portion 43 and the extension portion 44 are provided for each system. The fuse portion 43 of the first system is provided between the source island 421 and the drain island 412. The fuse portion 43 of the first system extends in the Y direction. The extension portion 44 of the first system extends from the side surface of the fuse portion 43 in the X direction. The termination 44a of the extension portion 44 is substantially flush with and exposed on the side surface 30e. The fuse portion 43 of the second system is provided between the source island 423 and the drain island 414. The fuse portion 43 of the second system extends in the Y direction. The extension portion 44 of the second system extends from the side surface of the fuse portion 43 in the X direction. The termination 44a of the extension portion 44 is substantially flush with and exposed on the side surface 30f. Each termination 44a is a cut surface by dicing.

The outflow passage 31 covers the outer peripheral surface of the extension portion 44 extending in the X direction over the entire length of the extension portion 44. The encapsulating body 30 includes an outflow passage 31 of the first system, which opens to the side surface 30e, and an outflow passage 31 of the second system, which opens to the side surface 30f. The other configurations of the present embodiment are similar to those of the preceding embodiment described above.

### Summary of Eighth Embodiment

The electronic device 20 of the present embodiment also achieves the similar effects to those achieved in the preceding embodiment described above. In present embodiment, when an abnormality occurs in the upper and lower arm circuit 10 of the first system and an overcurrent flows, the fuse portion 43 and the extension portion 44 of the first system melt. The molten portion flows to the outside of the encapsulating body 30 from the side surface 30e through the outflow passage 31 of the first system. When an abnormality occurs in the upper and lower arm circuit 10 of the second system and an overcurrent flows, the fuse portion 43 and the extension portion 44 of the second system melt. The molten portion flows to the outside of the encapsulating body 30 from the side surface 30f through the outflow passage 31 of the second system. In this way, it is possible to interrupt the electrical path of the system in which an abnormality has occurred. For example, when the electronic device 20 is used in a vehicle, only the faulty system is disconnected and the normal system can continue in a limp-home mode.

The extension portions 44 and the outflow passages 31 for the multiple systems are formed through the molding process for molding the encapsulating body and the singulation process. Thus, the manufacturing process can be simplified.

The electronic device 20 having the multiple systems is not limited to the 4-in-1 package structure. For example, the electronic device 20 may have a 6-in-1 package structure providing three systems. Although the example in which the outflow passages 31 for the multiple systems all open to the side surfaces of the encapsulating body 30 is illustrated, the present disclosure is not limited to this example. At least one of the outflow passages 31 may open to the back surface 30b or the one surface 30a. For example, one of the outflow passages 31 may open to the side surface and another one of the outflow passages 31 may open to the back surface 30b.

### Ninth Embodiment

A ninth embodiment is a modification based on the preceding embodiment(s), and the description of the preceding embodiment(s) may be referenced. In the preceding embodiment(s), the fuse portion, the extension portion, and a remaining portion of the wiring member excluding the fuse portion and the extension portion are integrally formed using the same material. Alternatively, the fuse portion and the extension portion may be formed using a material(s) different from that of the remaining portion of the wiring member.

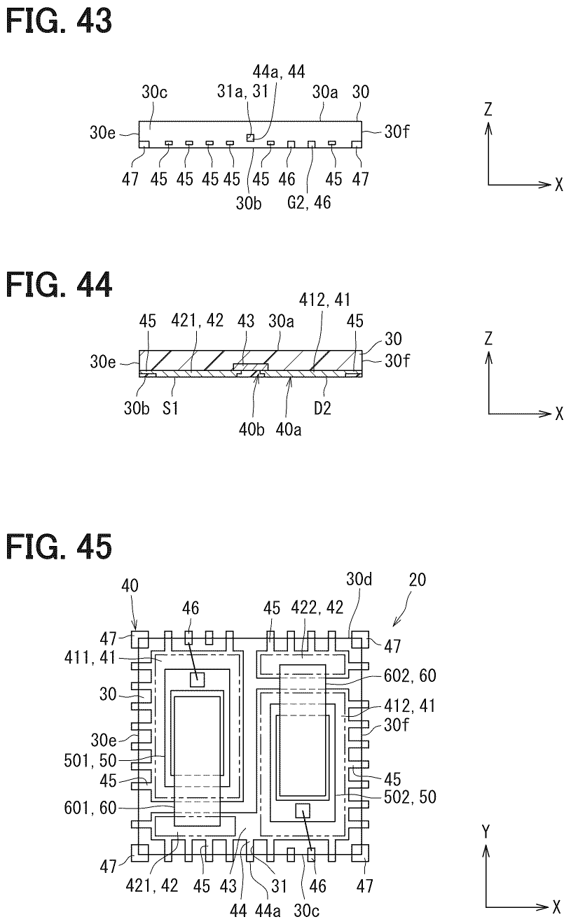

FIG. 42 is a plan view of the electronic device according to the present embodiment as viewed from the one surface side. FIG. 42 corresponds to FIG. 2. In FIG. 42, similar to FIG. 2, the encapsulating body is shown as transparent to indicate the portions covered by the encapsulating body. FIG. 43 is a side view as viewed in a direction along an arrow Y6 in FIG. 42. FIG. 44 is a cross-sectional view taken along a line XLIV-XLIV in FIG. 42.

The electronic device 20 of the present embodiment has substantially the similar structure to the electronic device 20 shown in FIG. 2. The difference is that the fuse portion 43 and the extension portion 44 are integrated with the remaining portion of the lead frame 40 other than the fuse portion 43 and the extension portion 44 by joining. The fuse portion 43 and the extension portion 44 are continuous and integral with each other. The fuse portion 43 and the extension portion 44 are formed as a single member using a common material. The fuse portion 43 and the extension portion 44 are formed using a metallic material having a lower melting point than the remaining portion of the lead frame 40. For example, the fuse portion 43 and the extension portion 44 are made of an aluminum (Al)-based alloy, and the remaining portion of the lead frame 40 is made of a Cu-based material.

The extension portion 44 extends in the Y direction from the side surface of the fuse portion 43, similar to the configuration shown in FIG. 2. The termination 44a of the extension portion 44 is substantially flush with the side surface 30c and exposed from the encapsulating body 30. The outflow passage 31 covers the outer peripheral surface of the extension portion 44 extending in the Y direction over the entire length of the extension portion 44. The encapsulating body 30 has an opening 31a of the outflow passage 31 on the side surface 30c. The fuse portion 43 and the extension portion 44 are disposed at a position farther from the lower surfaces of the islands 41 and 42 exposed from the back surface 30b of the encapsulating body 30 than the remaining portion of the lead frame 40. The other configurations of the present embodiment are similar to those of the preceding embodiment described above.

### Summary of Ninth Embodiment

The electronic device 20 of the present embodiment also achieves the similar effects to those achieved in the preceding embodiment described above. Additionally, in the present embodiment, the fuse portion 43 and the extension portion 44 are formed using a material having a lower melting point than the remaining portion of the lead frame 40. As a result, the temperature of the fuse portion 43 and the extension portion 44 can be more readily increased. That is, when an overcurrent flows, the fuse portion 43 and the extension portion 44 can thus be melted rapidly.

In present embodiment, the fuse portion 43 and the extension portion 44 are disposed at a higher position than the remaining portion of the lead frame 40, with reference to the lower surfaces of the islands 41 and 42 exposed from the back surface 30b of the encapsulating body 30. When the electronic device 20 is mounted on a substrate, the fuse portion 43 and the extension portion 44 are separated away from the conductor pattern of the substrate. This reduces the heat dissipation of the fuse portion 43 and the extension portion 44. That is, it is possible to facilitate the temperature increase of the fuse portion 43 and the extension portion 44.

Although the example in which the fuse portion 43 and the extension portion 44 of the lead frame 40 are formed using the material of lower melting point is illustrated, the present disclosure is not limited to this example. In the clip 60, the fuse portion 63 and the extension portion 64 may be formed using a material of lower melting point than a remaining portion of the clip 60 other than the fuse portion 63 and the extension portion 64. As another example, a material having a higher electrical resistivity may be used, instead of the material having the lower melting point. For example, the fuse portion 43 and the extension portion 44 may be formed using a material of higher electrical resistivity than the remaining portion of the lead frame 40. Similarly, the fuse portion 63 and the extension portion 64 may be formed using a material of higher electrical resistivity than the remaining portion of the clip 60 other than the fuse portion 63 and the extension portion 64.

### Tenth Embodiment

A tenth embodiment is a modification based on the preceding embodiment(s), and the description of the preceding embodiment(s) may be referenced. In the preceding embodiment(s), the termination of the extension portion is the cut surface made by dicing. Alternatively, the termination of the extension portion may be a cut surface made by press cutting.

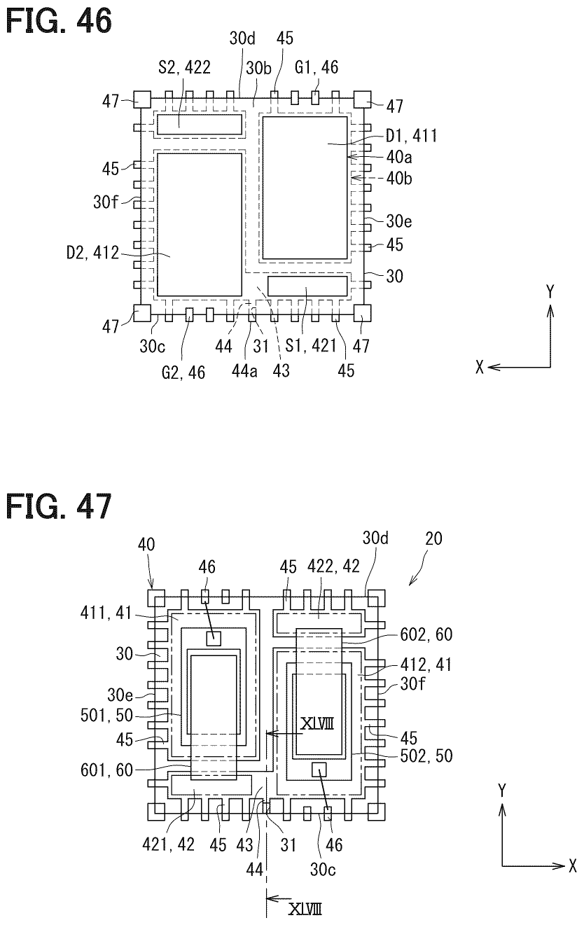

FIG. 45 is a plan view of the electronic device according to the present embodiment as viewed from the one surface side. FIG. 45 corresponds to FIG. 2. In FIG. 45, similar to FIG. 2, the encapsulating body is shown as transparent to indicate the portions covered by the encapsulating body. FIG. 46 is a plan view as viewed from the back surface side. FIG. 46 corresponds to FIG. 3.

The electronic device 20 of the present embodiment has substantially the similar structure to the electronic device 20 shown in FIG. 2. The difference is that the electronic device 20 is singulated by press cutting. The extension portion 44 extends beyond the side surface 30c. The termination 44a of the extension portion 44 is positioned outside the side surface 30c. The termination 44a is a cut surface made by press cutting. The support leads 45 also extend beyond the corresponding side surfaces 30c, 30d, 30e and 30f. The termination of the support lead 45 is also the cut surface made by press cutting.

The signal terminals 46 and the reinforcement terminals 47 are also press cut, similar to the extension portion 44. The signal terminals 46 extend beyond the corresponding side surfaces 30c, 30d, 30e and 30f. The reinforcement terminals 47 extend beyond the corresponding side surfaces 30c, 30d, 30e and 30f.

The electronic device 20 described above can be formed by utilizing the manufacturing method illustrated in the preceding embodiment. The difference is in the molding process for molding the encapsulating body 30P and the singulation process. The encapsulating body 30P is molded for each product unit. The encapsulating body 30P includes multiple encapsulating bodies 30 that are mutually separate. In the singulation, a press cutting is adopted instead of the dicing. As a result, it is possible to obtain the electronic device 20 in which the terminals protrude from the side surfaces 30c, 30d, 30e or 30f of the encapsulating body 30. The other configurations of the present embodiment are similar to those of the preceding embodiment described above.

### Summary of Tenth Embodiment

The electronic device 20 of the present embodiment also achieves the similar effects to those achieved in the preceding embodiment. For example, the surface condition is different between the termination 44a of the extension portion 44 and the fuse portion 43. The termination 44a is the cut surface. The outflow passage 31 opens on the side surface 30c of the encapsulating body 30. The extension portion 44 extends to the outside of the encapsulating body 30 through the opening 31a of the outflow passage 31. The termination 44a is the press-cut surface, and the fuse portion 43 has the etched surface. The extension portion 44 and the outflow passage 31 are formed through the molding process for molding the encapsulating body and the singulation process. Therefore, the manufacturing process can be simplified.

The electronic device 20 is not limited to a flat package in which the lead frame 40 is exposed on the back surface 30b to be substantially flush with the back surface 30b. The shape of the exposed terminals is not particularly limited. For example, the electronic device 20 may have a package structure with gull-wing type terminals protruding, such as a QFP. QFP is an abbreviation for a quad flat package.

### Eleventh Embodiment

An eleventh embodiment is a modification based on the preceding embodiment(s), and the description of the preceding embodiment(s) may be referenced. In the preceding embodiment(s), the extension portion is made to protrude from the side surface by the press cutting. Alternatively, the termination of the extension portion may be located at an intermediate position within the outflow passage by extracting after the press cutting.

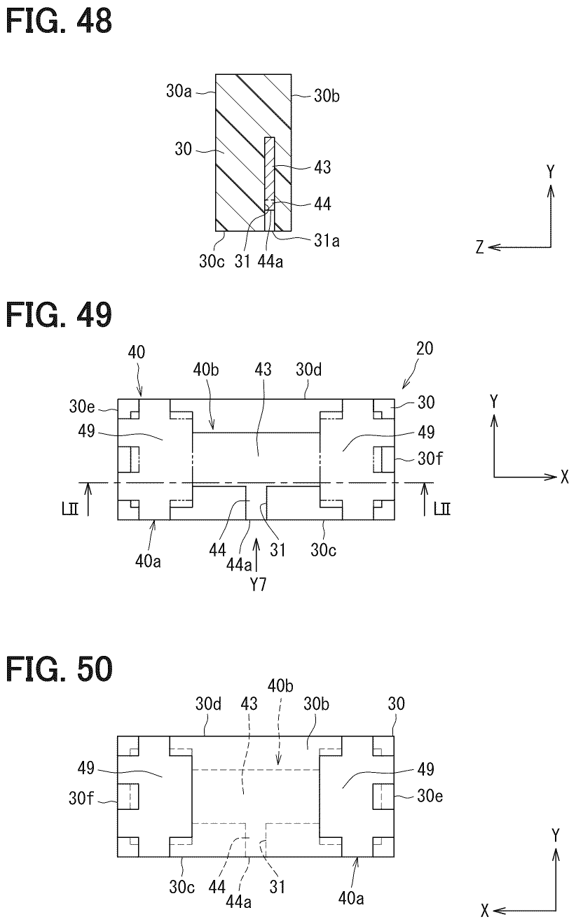

FIG. 47 is a plan view of the electronic device according to the present embodiment as viewed from the one surface side. FIG. 47 corresponds to FIG. 45. In FIG. 47, similar to FIG. 2, the encapsulating body is shown as transparent to indicate the portions covered by the encapsulating body. FIG. 48 is a cross-sectional view taken along a line XLVIII-XLVIII in FIG. 47.

The electronic device 20 of the present embodiment has substantially the similar structure to the electronic device 20 shown in FIG. 45. The difference is that, after the press cutting, the extension portion 44 is extracted, so that the termination 44a of the extension portion 44 is located at an intermediate position within the outflow passage 31. A part of the extension portion 44 is removed by extracting, and a remaining portion becomes the extension portion 44 of the electronic device 20. The termination 44a is a fractured surface resulting from the extracting.

The outflow passage 31 is formed during molding of the encapsulating body 30P, that is, before the extracting. The outflow passage 31 is formed reflecting the extension portion 44 before the extracting, and opens on the side surface 30c. The support leads 45 are not subjected to the extracting process and extend beyond the corresponding side surfaces 30c, 30d, 30e, and 30f. The termination of the support lead 45 is the cut surface by the press cutting. The other configurations of the present embodiment are similar to those of the preceding embodiment.

### Summary of Eleventh Embodiment

The electronic device 20 of the present embodiment also achieves the similar effects to those achieved in the preceding embodiment. For example, the encapsulating body 30 includes the outflow passage 31 formed by covering the extension portion 44 and originating from the extension portion 44. The outflow passage 31 extends along the extension portion 44 and opens on the side surface 30c of the encapsulating body 30. Before the extension portion 44 melts, the outflow passage 31 is blocked by the extension portion 44. When the extension portion 44 melts, the outflow passage 31 functions as a passage for releasing the melted fuse portion 43 and extension portion 44 to the outside of the encapsulating body 30. Thus, even if the mold used for molding the encapsulating body 30 is not brought into contact with the fuse portion 43, the fuse portion 43, which is melted by energization, can be released to the outside of the encapsulating body 30. The fuse portion 43 can exhibit the desired interrupting characteristic.

The termination 44a of the extension portion 44 is the fractured surface and is located at an intermediate position within the outflow passage 31. Such an extension portion 44 is formed by extracting after press cutting. The length of the extension portion 44 can be shortened while securing the outflow passage 31. That is, the extension portion 44 can be made to melt more easily, and the melted fuse portion 43 can be quickly released to the outside of the encapsulating body 30. Even if the extension portion 44 and the fuse portion 43 are fractured at a boundary surface between the extension portion 44 and the fuse portion 43 during extracting, fine protrusions may be formed on the fractured surface due to the tensile force. That is, at least a part of the termination 44a is located at an intermediate position within the outflow passage 31.

### Twelfth Embodiment

A twelfth embodiment is a modification based on the preceding embodiment(s), and the description of the preceding embodiment(s) may be referenced. In the preceding embodiment(s), the electronic device includes the semiconductor element. Alternatively, the electronic device may be configured without a semiconductor element. The electronic device may be configured to include only the wiring member and the encapsulating body.

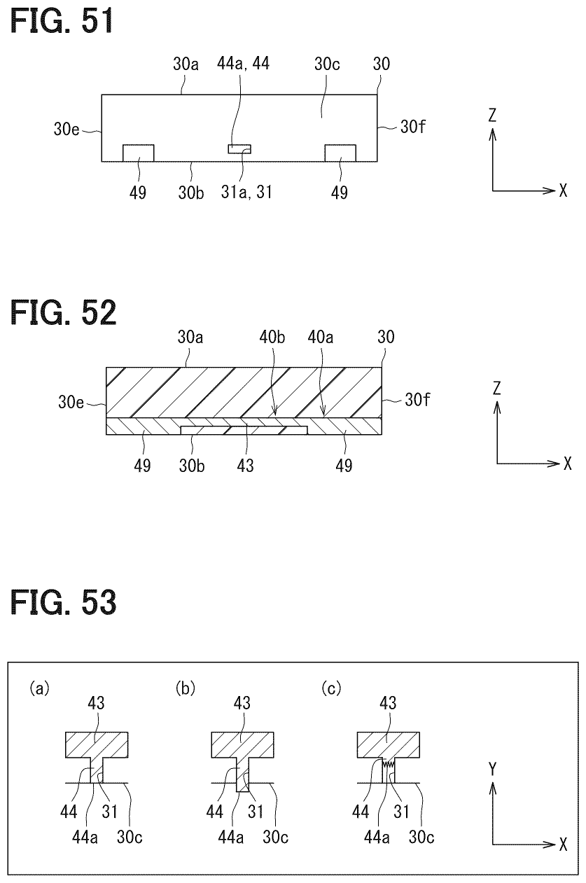

FIG. 49 is a plan view of the electronic device according to the present embodiment as viewed from the one surface side. FIG. 49 corresponds to FIG. 2. In FIG. 49, similar to FIG. 2, the encapsulating body is shown as transparent to indicate the portions covered by the encapsulating body. FIG. 50 is a plan view as viewed from the back surface side of the electronic device. FIG. 50 corresponds to FIG. 3. FIG. 51 is a side view as viewed in a direction along an arrow Y7 in FIG. 49. FIG. 52 is a cross-sectional view taken along a line LII-LII in FIG. 49.

The electronic device 20 of the present embodiment provides a fuse. The electronic device 20 includes only the encapsulating body 30 and the lead frame 40, which is the wiring member. The encapsulating body 30 has a substantially rectangular shape in the plan view, similar to the preceding embodiment. The encapsulating body 30 has the one surface 30a, the back surface 30b, and the side surfaces 30c, 30d, 30e, and 30f. The lead frame 40 is formed, for example, by etching similar to the preceding embodiment. The lead frame 40 has the thick portion 40a and the thin portion 40b. The upper surface of the lead frame 40 is entirely covered by the encapsulating body 30. The lower surface of the thick portion 40a of the lead frame 40 is substantially flush with the back surface 30b and exposed from the back surface 30b, and the lower surface of the thin portion 40b is covered by the encapsulating body 30.

The lead frame 40 includes the fuse portion 43, the extension portion 44, and terminal portions 49. The fuse portion 43 extends in the X direction, and the terminal portions 49 are provided at both ends of the fuse portion 43 in the X direction. Most of the terminal portion 49 is made of the thick portion 40a. The terminal portion 49 is exposed from the back surface 30b and connected to a substrate. In the plan view, the thin portion 40b is provided at a portion of the outer peripheral edge of the terminal portion 49. It should be noted that the double-dotted chain line in FIG. 49 indicates the boundary between the thick portion 40a and the thin portion 40b. Since the terminal portion 49 has both the thick portion 40a and the thin portion 40b, it is possible to restrict the lead frame 40 from being slipped from the encapsulating body 30 by the anchor effect. The fuse portion 43 and the extension portion 44 each have only the thin portion 40b.

The extension portion 44 extends in the Y direction from the side surface of the fuse portion 43. The termination 44a of the extension portion 44 is substantially flush with the side surface 30c and exposed from the encapsulating body 30. The termination 44a is the cut surface made by dicing. The outflow passage 31 covers the outer peripheral surface of the extension portion 44 extending in the Y direction over the entire length of the extension portion 44. The encapsulating body 30 has the opening 31a of the outflow passage 31 on the side surface 30c. The outflow passage 31 extends substantially parallel to the lower surface of the terminal portion 49 exposed from the encapsulating body 30. The electronic device 20 described above can be obtained by preparing the lead frame 40P, molding the encapsulating body 30P, and then dicing.

### Summary of Twelfth Embodiment

The electronic device 20 of the present embodiment also achieves the similar effects to those described in the preceding embodiment. For example, when an overcurrent flows, the fuse portion 43 melts and interrupts the electrical path. Further, the lead frame 40 includes the extension portion 44. The encapsulating body 30 includes the outflow passage 31 formed by covering the extension portion 44 and originating from the extension portion 44. Before the extension portion 44 melts, the outflow passage 31 is blocked by the extension portion 44. When the extension portion 44 melts, the outflow passage 31 functions as a passage for releasing the melted fuse portion 43 and extension portion 44 to the outside of the encapsulating body 30. Thus, even if the mold for molding the encapsulating body 30 is not brought into contact with the fuse portion 43, the fuse portion 43 melted by energization can be released to the outside of the encapsulating body 30. The fuse portion 43 can exhibit the desired interrupting characteristic.

In the present embodiment, the electronic device 20 is singulated by dicing. The lead frame 40 is formed by etching. By dicing, the termination 44a is substantially flush with the side surface 30c and exposed from the encapsulating body 30, and the outflow passage 31 opens on the side surface 30c. The termination 44a is the cut surface made by the dicing, and the fuse portion 43 has the etched surface. The extension portion 44 and the outflow passage 31 are formed through the molding process of molding the encapsulating body and the singulation process. Thus, the manufacturing process can be simplified.

Although the example in which the electronic device 20 is singulated by dicing is illustrated, the present disclosure is not limited to this example. The electronic device 20 may be singulated by press cutting, or may be formed by extracting a part of the extension portion 44 after press cutting.

### Thirteenth Embodiment

A thirteenth embodiment is a modification based on the preceding embodiment(s), and the descriptions of the preceding embodiment(s) may be referenced. In the present embodiment(s), various forms of the extension portion 44 that may be adopted by the electronic device 20 will be described.

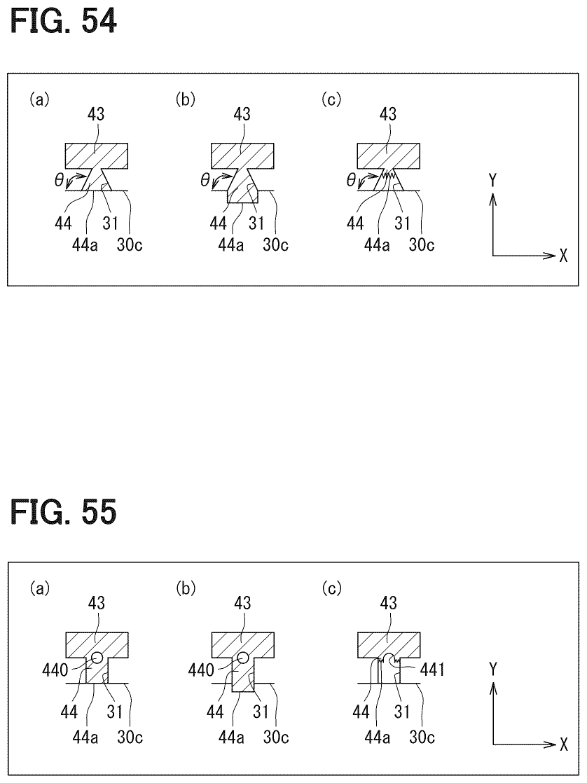

FIG. 53 is a diagram showing cross-sectional views of examples of the extension portion of the electronic device according to the present embodiment. FIGS. 54 and 55 are diagrams showing cross-sectional views of other examples of the extension portion. In FIGS. 53 to 55, the cross-sectional views are taken along the XY plane. For convenience, in FIGS. 53 to 55, only the fuse portion and the extension portion of the lead frame are illustrated, and the fuse portion and the extension portion are shown with hatchings. In each figure, (a) shows the lead frame by dicing cut, (b) shows the lead frame by press cutting, and (c) shows the lead frame by press cutting and extracting afterwards. In all examples, since the exposed interface of the fuse portion is not formed by the mold for molding the encapsulating body, it is easy to manufacture.

FIG. 53 illustrates the configuration exemplified in the preceding embodiment. The extension portion 44 extends in the Y direction with a predetermined width, i.e., a predetermined cross-sectional area. The outflow passage 31 extends in the Y direction and opens on the side surface 30c. In (a) of FIG. 53, the termination 44a is substantially flush with the side surface 30c and exposed on the side surface 30c due to the dicing cut. In (b) of FIG. 53, the termination 44a is positioned outside the side surface 30c due to the press cutting. Pressing burrs and the like may be present on the termination 44a, which is the cut surface. In (c) of FIG. 53, the termination 44a is a fractured surface formed by extracting after the press cutting. In the preceding embodiment, the fractured surface is shown in a simplified manner. The termination 44a is located at an intermediate position in the outflow passage 31.

In FIG. 54, the extension portion 44 is formed so that its width increases as it approaches the side surface 30c. As a result, the outflow passage 31 has a tapered shape. An angle θ is formed between the side surface 30c and a side surface of the extension portion 44 in the plan view. That is, the angle θ is formed between the side surface 30c and the wall surface (side wall) of the outflow passage 31 in the plan view. The angle θ may also be referred to as the taper angle. In the examples shown in FIG. 53, the angle θ is approximately 90 degrees. In the examples shown in FIG. 54, the angle θ is greater than 90 degrees. In (a) of FIG. 54, the extension portion 44 becomes wider as it approaches the side surface 30c and terminates substantially flush with the side surface 30c. In (b) of FIG. 54, the extension portion 44 becomes wider as it approaches the side surface 30c, and further extends outside the side surface 30c in the Y direction with a constant width. In (c) of FIG. 54, the extension portion 44 terminates at an intermediate position in the tapered outflow passage 31.

In FIG. 55, a through-hole 440 or a recess 441 derived from the through-hole 440 is formed in the vicinity of the end of the extension portion 44. In (a) and (b) of FIG. 55, the through-hole 440 is formed in the vicinity of the end of the extension portion 44 with respect to the configuration shown in FIG. 53. In (c) of FIG. 55, for example, the extension portion 44 shown in (b) of FIG. 55 is extracted and fractured at the part of the through-hole 440. The termination 44a of the extension portion 44 is located at an intermediate position in the outflow passage 31. The termination 44a includes the recess 441 derived from the through-hole 440. At the termination 44a, the portion excluding the recess 441 is a fractured surface.

### Summary of Thirteenth Embodiment

As illustrated in the present embodiment, in a configuration in which the outflow passage 31 extends in one direction (Y direction), it is preferable that the angle θ formed between the outer surface (side surface 30c) of the encapsulating body 30 and the wall surface of the outflow passage 31 is at least 90 degrees. More preferably, the angle θ is greater than 90 degrees. This facilitates the extracting process. That is, it becomes easier to form the extension portion 44 in which the termination 44a is the fractured surface and is located in an intermediate position in the outflow passage 31. Moreover, it is easier to release the melted fuse portion 43 and extension portion 44 to the outside of the side surface 30c through the outflow passage 31.

By forming the through-hole 440 as shown in FIG. 55 or an unpenetrated notch (not shown), the extension portion 44 can be extracted at a predetermined intermediate position in the outflow passage 31. That is, it becomes easier to form the extension portion 44 in which the termination 44a has a fractured surface and is located at an intermediate position in the outflow passage 31. In addition, the amount of the extension portion 44 can be reduced by the presence of the through-hole 440 or notch. Thus, it becomes easier to release the melted fuse portion 43 and extension portion 44 to the outside of the side surface 30c through the outflow passage 31.

### Other Embodiments

The disclosures in this specification and drawings are not limited to the illustrated embodiments. The disclosure includes the illustrated embodiments and modifications thereof by those skilled in the art based thereon. For example, the disclosure is not limited to the combinations of parts and/or elements illustrated in the embodiments. The disclosure can be implemented in various combinations. The disclosure may include additional parts that can be added to the embodiments. The disclosure also includes embodiments from which parts and/or elements are omitted. The disclosure includes embodiments with replacement or combination of parts and/or elements between the embodiments. The technical scope disclosed is not limited to the descriptions of the embodiments. Several technical scopes disclosed should be understood to include all modifications falling within the gist of the present disclosure.

When an element or layer is referred to as being “on”, “connected to”, “coupled to”, or “joined to” another element or layer, it may be directly on, connected to, coupled to, or joined to the other element or layer, or intervening elements or layers may be present. In contrast, when an element is referred to as being “directly on”, “directly connected to”, “directly coupled to”, or “directly joined to” another element or layer, no intervening elements or layers are present. Other words used to describe the relationship between elements should be interpreted similarly (for example, “between” vs. “directly between”, “adjacent” vs. “directly adjacent”, etc.). As used herein, the term “and/or” includes any and all combinations of one or more of the associated listed items. At least one of A or B includes at least A, at least B, and both A and B.

Spatially relative terms such as “inner”, “outer”, “back”, “lower”, “low”, “upper”, “high”, etc., may be used herein for ease of description to describe the relationship of one element or feature to another as illustrated in the figures. It is to be understood that spatially relative terms are intended to encompass different orientations in addition to the orientation depicted in the drawings. For example, if the device in the figures is turned over, elements described as “lower” or “beneath” other elements or features would then be oriented “upper”. Accordingly, the term “lower” can encompass both upward and downward orientations. The device may be oriented in other ways (rotated 90 degrees or to other orientations), and the spatially relative descriptors used herein should be interpreted accordingly.

What is claimed is:

1. An electronic device comprising:
a wiring member including a fuse portion extending in a predetermined direction; and
an encapsulating body encapsulating the wiring member, wherein
the wiring member includes an extension portion that is continuous and integral with the fuse portion, extends in a direction different from the predetermined direction at least in a portion thereof, and is melted by heat generated from the fuse portion due to energization; and
the encapsulating body includes an outflow passage that has a portion covering an outer peripheral surface of the extension portion, and extends along the extension portion and defines an opening on an outer surface of the encapsulating body for releasing the fuse portion and the extension portion, which are melted due to the energization, outside of the encapsulating body.

2. The electronic device according to claim 1, wherein
a surface condition of a termination of the extension portion is different from a surface condition of the fuse portion.

3. The electronic device according to claim 2, wherein
the termination of the extension portion is a cut surface.

4. The electronic device according to claim 3, wherein
the termination of the extension portion is flush with the outer surface of the encapsulating body.

5. The electronic device according to claim 3, wherein
the extension portion extends to a position outside of the encapsulating body through the opening of the outflow passage.

6. The electronic device according to claim 2, wherein
the end of the extension portion has a fractured surface and is located at an intermediate position in the outflow passage.

7. The electronic device according to claim 2, wherein
the encapsulating body has a first surface, a second surface opposite to the first surface in a thickness direction of the fuse portion, and a side surface continuous with the first surface and the second surface, and
the outflow passage defines the opening on the side surface.

8. The electronic device according to claim 7, wherein
a cross-sectional area of the extension portion is smaller than a cross-sectional area of the fuse portion.

9. The electronic device according to claim 7, wherein
the outflow passage extends in one direction, and
an angle defined between the outer surface of the encapsulating body and a wall surface of the outflow passage is at least 90 degrees.

10. The electronic device according to claim 7, wherein
the wiring member is a lead frame.

11. The electronic device according to claim 10, further comprising:
a semiconductor element encapsulated in the encapsulating body, wherein
the lead frame includes a mounting portion that is thicker than the fuse portion and the extension portion and has a connection surface to which the semiconductor element is connected, and
the mounting portion has a lower surface opposite to the connection surface,
the lower surface of the mounting portion is exposed from the encapsulating body, and
a lower surface of the fuse portion and a lower surface of the extension portion are covered by the encapsulating body.

12. The electronic device according to claim 11, wherein
the outflow passage is parallel to the lower surface of the mounting portion exposed from the encapsulating body.

13. The electronic device according to claim 7, further comprising:
a semiconductor element; and
a circuit element different from the wiring member and the semiconductor element, wherein
the encapsulating body encapsulates the semiconductor element and the circuit element together with the wiring member, and
the wiring member is a clip electrically connecting the semiconductor element and the circuit element.

14. The electronic device according to claim 11, wherein
the semiconductor element includes a plurality of semiconductor elements provided for a plurality of systems, and
the fuse portion of the wiring member is provided for each of the plurality of systems.

15. The electronic device according to claim 1, wherein
the fuse portion and the extension portion are each made of a material having a lower melting point than a remaining portion of the wiring member other than the fuse portion and the extension portion, or of a material having a higher electrical resistivity than the remaining portion of the wiring member.
